(19) United States
(12) Patent Application Publication
(10) Pub. No.: US 2026/0215249 A1
(43) Pub. Date: Jul. 23, 2026

(54) CELL REGIONS AND METHODS OF MANUFACTURING SAME

(71) Applicant: TAIWAN SEMICONDUCTOR MANUFACTURING COMPANY, LTD., Hsinchu (TW)

(72) Inventors: Yo-Shiuan LIN, Hsinchu (TW); Kuang-Ching CHANG, Hsinchu (TW); Wei-Hsin TSAI, Hsinchu (TW); Jung-Chan YANG, Hsinchu (TW); Wei-Ling CHANG, Hsinchu (TW); Cheng-Yu LIN, Hsinchu (TW)

(21) Appl. No.: 19/221,770

(22) Filed: May 29, 2025

Related U.S. Application Data
(60) Provisional application No. 63/748,690, filed on Jan. 23, 2025.

(51) Int. Cl. H01L 23/528; H10D 30/01; H10D 30/62; H10D 84/01; H10D 84/85

(52) U.S. Cl. CPC H10W 20/43; H10D 30/024; H10D 30/6211; H10D 84/0179; H10D 84/0193; H10D 84/853; H10D 84/856; H10W 20/427

(57) ABSTRACT

A semiconductor device includes a first cell region including: adjacent first and second active regions; gate segments including first and second gate segments; and segments in a first metallization (M_1st) layer including adjacent first, second and third M_1st power grid (PG) segments correspondingly configured for first, second and the first reference voltages, the first and second reference voltages being different, the M_1st PG segments aligning to corresponding ones of alpha tracks; top and bottom boundaries of the first cell region aligning to corresponding ones of alpha tracks; the first M_1st PG segment substantially asymmetrically overlapping the first active region; the second M_1st PG segment overlapping the bottom boundary, being adjacent to the second active region and substantially free from overlapping the first and second active regions; and the top boundary being between, and substantially free from overlapping each of the first active region and the third M_1st PG segment.

### PRIORITY CLAIM

The application claims the priority of U.S. Provisional Application No. 63/748,690, filed Jan. 23, 2025, which is incorporated herein by reference in its entirety.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIGS. 1A-1C are corresponding block diagrams, in accordance with some embodiments.

FIGS. 2A-2F are corresponding layout diagrams, in accordance with some embodiments.

FIGS. 3A-3B are corresponding layout diagrams, in accordance with some embodiments.

FIGS. 4A-4B are corresponding schematic circuit diagram, in accordance with some embodiments.

FIGS. 4C-4D are corresponding floorplan diagrams, in accordance with some embodiments.

FIGS. 4E-4F are corresponding layout diagrams, in accordance with some embodiments.

FIGS. 5A-5B are corresponding cross-sections, in accordance with some embodiments.

FIGS. 6 and 7 are flowcharts of corresponding methods, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a semiconductor device includes a first cell region including: adjacent first and second active regions; gate segments including first and second gate segments; first and second insulation structures adjacent ends correspondingly of the first and second gate segments; and segments in a first metallization (M_1st) layer including adjacent first, second and third M_1st power grid (PG) segments correspondingly configured for first, second and the first reference voltages, the first and second reference voltages being different, the M_1st PG segments aligning to corresponding ones of alpha tracks; top and bottom boundaries of the first cell region extending in the first direction, being at least proximal to the first and second insulation structures, and aligning to corresponding ones of alpha tracks; the first M_1st PG segment substantially asymmetrically overlapping the first active region; the second M_1st PG segment overlapping the bottom boundary, being adjacent to the second active region and substantially free from overlapping the first and second active regions; and the top boundary being between, and substantially free from overlapping each of the first active region and the third M_1st PG segment. The first cell region has a height of about 1.5*SH, i.e., has a height that is about a 1.5 multiple of the height SH of a single height cell region. In some embodiments, the first cell region is referred to as a one-and-one-half height cell region. In some embodiments, the first cell region is referred to as a three-halves half height cell region.

According to a first other approach, two single height cell regions are stacked on each other relative to the Y-axis (in a two-stack arrangement) which represents a counterpart to the first cell. The counterpart two-stack has: the same width as the first cell region; a net height of 2.0*SH; a P-type active region density of 2*d_ARP_SH, where d_ARP_SH is the P-type active region density of the single height cell region; and an N-type active region density of 2*d_ARN_SH, where d_ARP_SH is the P-type active region density of the single height cell region, and where d_ARN_SH=d_ARP_SH. As compared to the counterpart two-stack, the first cell region has: a density of P-type active region d_ARP_2A=1.87*d_AR_SH despite having a relatively shorter height of 1.5*SH; and a density of N-type active region d_ARN_2A≈1.87*d_AR_SH despite having a relatively shorter height of 1.5*SH. In some embodiments, relative to the Y-axis, active region 208N(1) is not as wide as active region 208P(1) in the first cell region. In some of such embodiments, as compared to the counterpart two-stack, the first cell region has: a density of P-type active region d_ARP_2A≈1.87*d_AR_SH despite having a relatively shorter height of 1.5*SH; and a density of N-type active region d_ARN_2A=0.94*d_AR_SH.

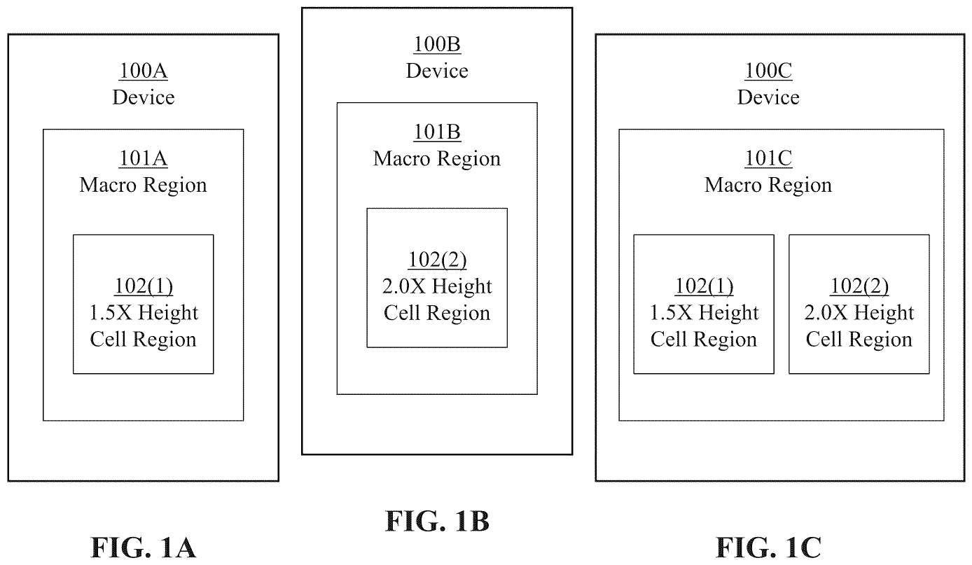

FIGS. 1A-1C are block diagrams of corresponding devices 100A, 100B and 100C, in accordance with some embodiments.

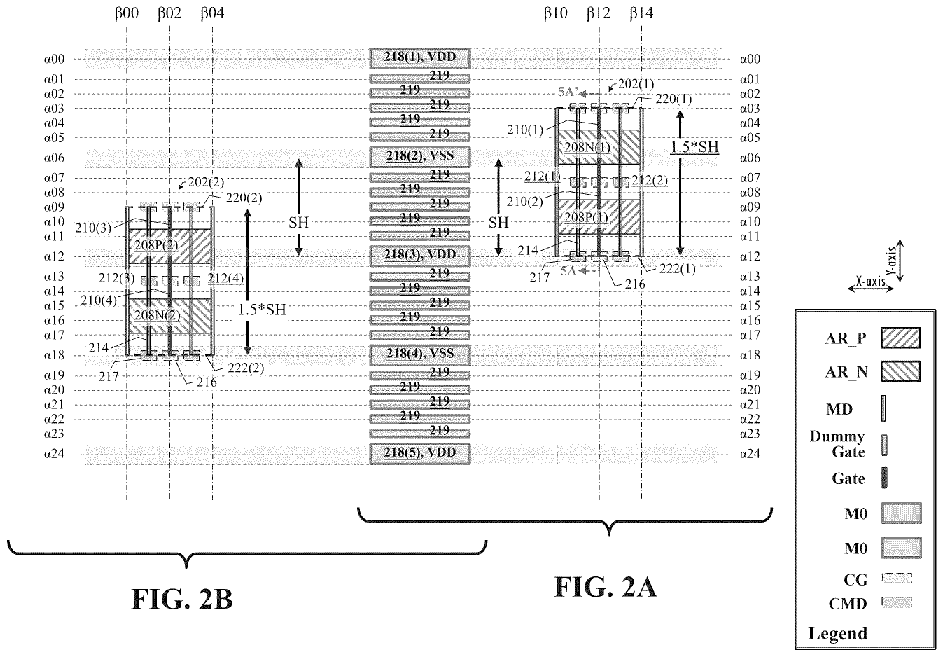

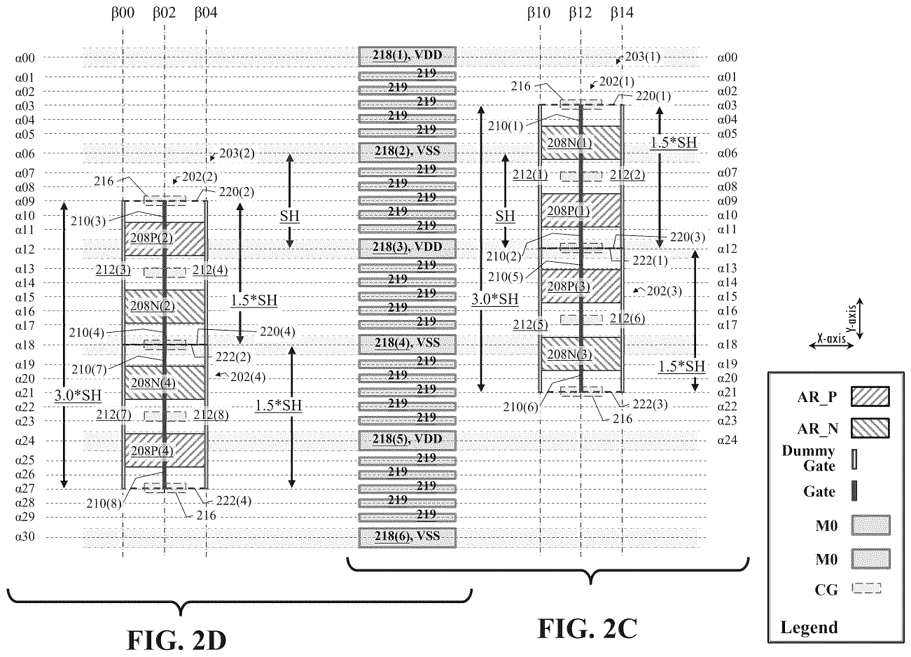

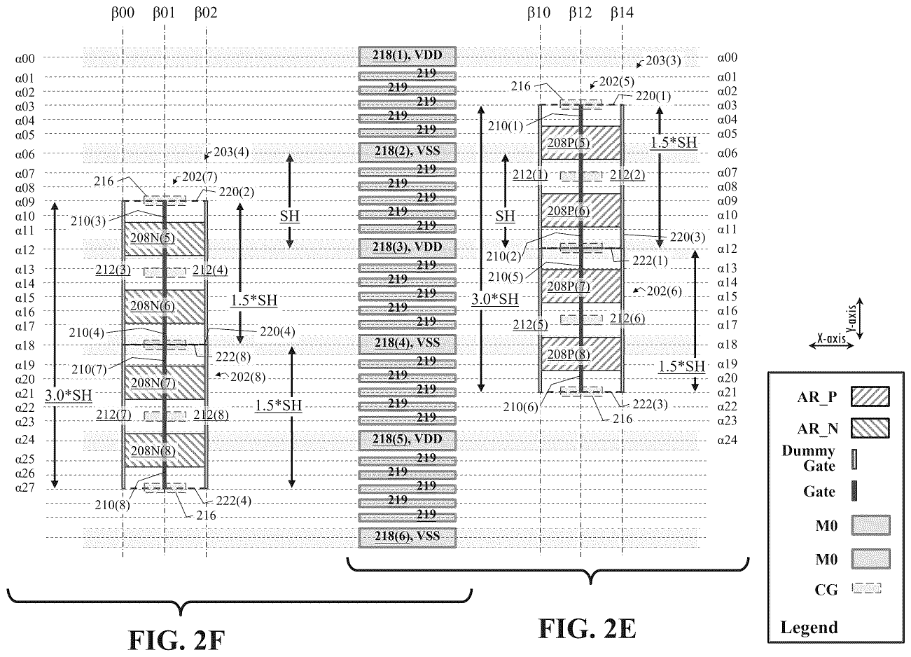

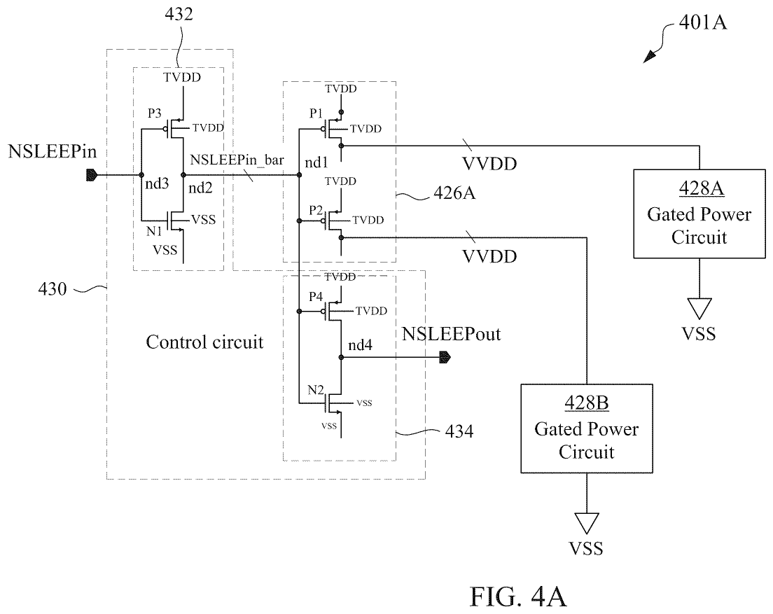

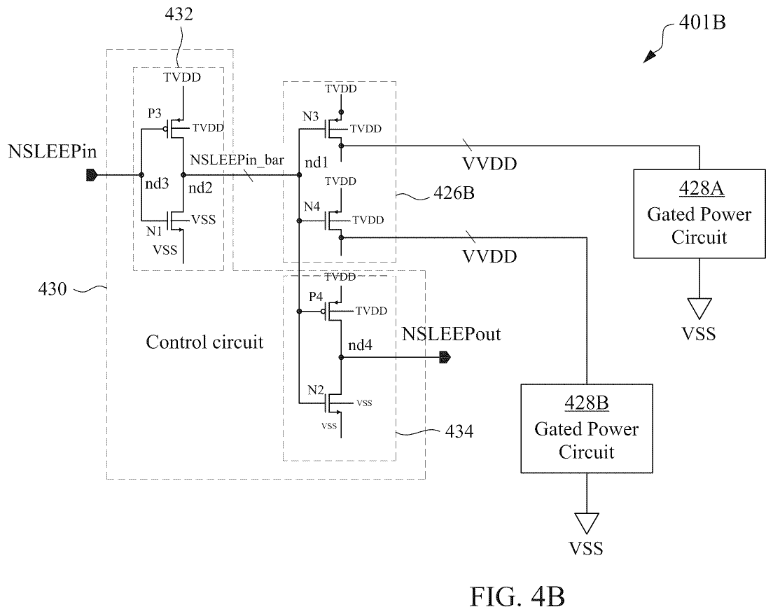

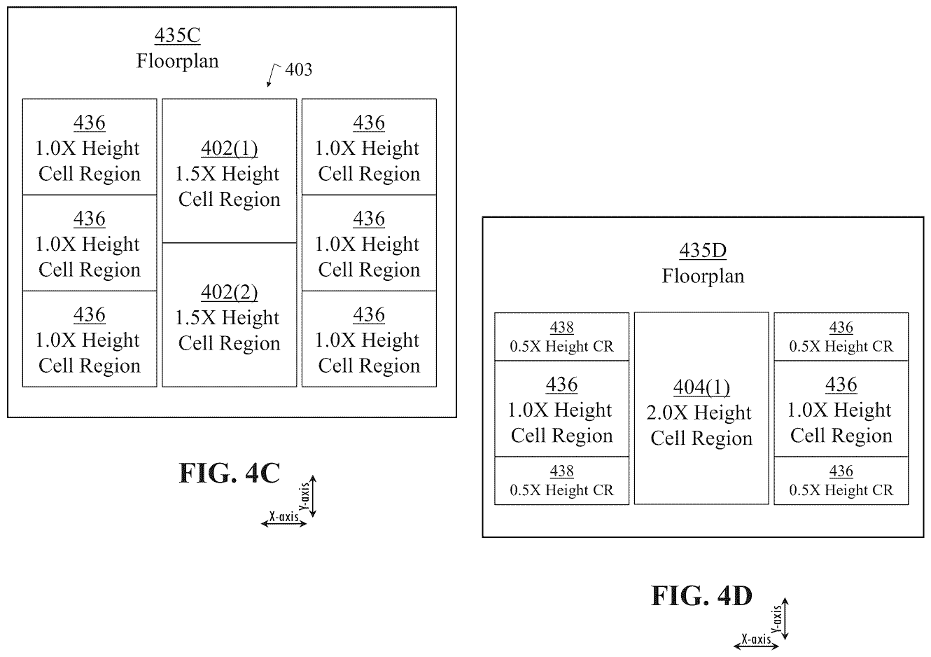

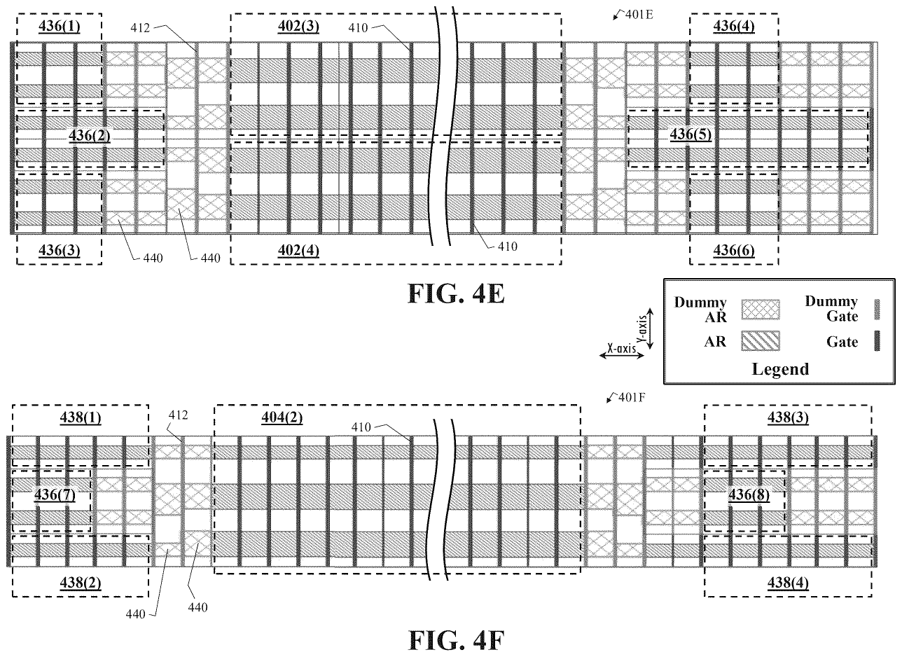

Each of devices 100A-100C is an example of an integrated circuit (IC). In some embodiments, each of devices 100A-100C is referred to as a semiconductor device. Devices 100A, 100B and 100C correspondingly include macro regions 101A, 101B and 101C. Macro region 101A includes a functional cell region 102(1) having a height that is about a 1.5 multiple of the height of a single height cell region (see. e.g., FIGS. 2A-2E), where the height of a single height cell region is determined according to one or more design rules of a corresponding semiconductor process technology node. Macro region 101B includes a functional cell region 102(2) having a height that is about a 2.0 multiple of the height of the single height cell region (see. e.g., instances of cell region 436(1) of FIG. 4C, instances of cell region 436 of FIG. 4D, or the like). Macro region 101C includes functional cell region 102(1) and functional cell region 102(2). In some embodiments, each of functional cell regions 102A-102C includes one or more active devices, passive devices, or the like. Examples of active devices or active elements include, but are not limited to, transistors, diodes, or the like. Examples of passive elements include, but are not limited to, capacitors, inductors, fuses, resistors, or the like.

In some embodiments, macro region 101A is comprised of one or more instances of functional cell region 102A and (optionally) one or more other functional cell regions. In such embodiments, macro region 101A is configured to provide/execute a given computational function which is comprised of less complicated functions provided correspondingly by the one or more instances of functional cell region 102A and/or the one or more other functional cell regions. In some embodiments, one or more instances of functional cell region 102A and/or one or more other functional cell regions represent intercoupled building blocks which comprise macro region 101A.

In some embodiments, macro region 101B is comprised of one or more instances of functional cell region 102B and (optionally) one or more other functional cell regions. In such embodiments, macro region 101B is configured to provide/execute a given computational function which is comprised of less complicated functions provided correspondingly by the one or more instances of functional cell region 102B and/or the one or more other functional cell regions. In some embodiments, one or more instances of functional cell region 102B and/or one or more other functional cell regions represent intercoupled building blocks which comprise macro region 101B.

In some embodiments, macro region 101C is comprised of one or more instances of functional cell region 102(1), one or more instances of cell region 102(2) and (optionally) one or more other functional cell regions. In such embodiments, macro region 101C is configured to provide/execute a given computational function which is comprised of less complicated functions provided correspondingly by the one or more instances of functional cell region 102(1), the one or more instances of functional cell region 102(2) and (optionally) the one or more other functional cell regions. In some embodiments, one or more instances of functional cell region 102(1), one or more instances of functional cell region 102(2) and (optionally) one or more other functional cell regions represent intercoupled building blocks which comprise macro region 101C.

In some embodiments, each of macro regions 101A-101C is understood in the context of an analogy to the architectural hierarchy of modular programming, in which subroutines/procedures are called by a main program (or by other subroutines) to carry out a given computational function. In this context, devices 100A-100C correspondingly use macro regions 101A-101 to perform one or more given functions. Accordingly, in this context and in terms of architectural hierarchy, each of devices 100A-100C is analogous to the main program and each of macro regions 101A-101C is analogous to subroutines/procedures. In some embodiments, each of macro regions 101A-101C is a soft macro. In some embodiments, each of macro regions 101A-101C is a hard macro. In some embodiments, each of macro regions 101A-101C is a soft macro which is described digitally in register-transfer level (RTL) code. In some embodiments, synthesis, placement, and routing have yet to have been performed on each of macro regions 101A-101C such that the corresponding soft macro can be synthesized, placed, and routed for a variety of process technology nodes. In some embodiments, each of macro regions 101A-101C is a hard macro which is described digitally in a binary file format (e.g., Graphic Database System II (GDSII) stream format), where the binary file format represents planar geometric shapes, text labels, other information, and the like of one or more layouts correspondingly of each of macro regions 101A-101C in hierarchical form. In some embodiments, a binary file format is referred to as a non-text file format. In some embodiments, synthesis, placement, and routing have been performed on macro region 101 such that the hard macro is specific to a particular process technology node.

In some embodiments, examples of functions provided by a macro region (e.g., macro region 101A, 101B and/or 101C) include a memory, a power grid, a clock tree, an adder, a phase-locked loop (PLL), a delay-locked loop (DLL), a flip-flop, a shift register, an analog-to-digital converter (ADC), a digital-to-analog converter (DAC), interfaces, higher-level Boolean logic, or the like. Example memories include a static random access memory (SRAM), a dynamic RAM (DRAM), a resistive RAM, a magnetoresistive RAM (MRAM), a read only memory (ROM), or the like. An example of a flip-flop is a scan-insertion type of D flip-flop (SDFQ), or the like. In some embodiments, examples of functions provided by functional cell regions (e.g., functional cell region 102) include an inverter, a tri-state inverter, a buffer, a latch a multiplexer (MUX), a driver, a latch, delay, a half adder, a full adder, a compressor, lower-level Boolean logic, or the like, Examples of lower-level Boolean logic include AND, OR, NAND, NOR, XOR, INV, AND-OR-Invert (AOI), OR-AND-Invert (OAI), or the like.,

Each of functional cell regions 102(1)-101(2) includes corresponding segments in one or more metallization layers. Figures of the present disclosure assume a Cartesian coordinate system (unless noted otherwise) in which first, second and third directions are, e.g., correspondingly parallel to the X-axis, the Y-axis and the Z-axis. In some embodiments, the first to third directions correspond to directions other than the X-axis, Y-axis and Z-axis. In some embodiments, long and short axes of the segments extend correspondingly in the first and second directions in even ones of the metallization layers; in such embodiments, long and short axes of the segments extend correspondingly in the second and first directions in odd ones of the metallization layers. In such embodiments, boundaries of functional cell region 102 are described in terms of the first and second directions.

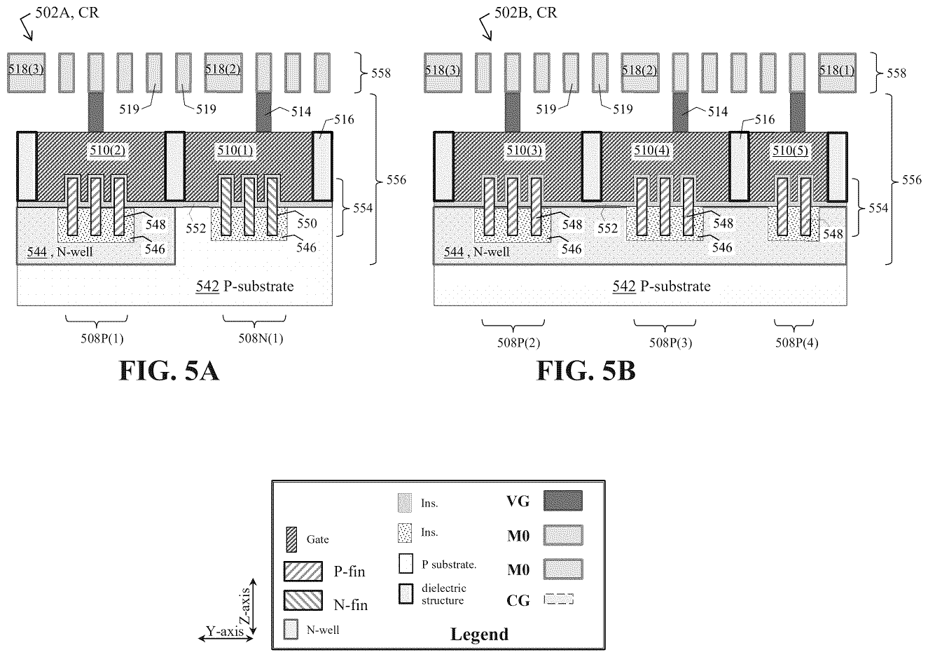

In some embodiments, each of functional cell regions 102(1)-101(2) corresponds to a transistor-components layer (see, e.g., FIGS. 5A-5B) having circuitry components, e.g., transistors, formed thereon in a front-end-of-line (FEOL) fabrication. Correspondingly in each of functional cell regions 102(1)-102(2), above and/or below an active region (AR) layer (see, e.g., FIGS. 5A-5B), various metal layers are interleaved with corresponding interconnection layers are stacked over and/or under insulating layers in a back end of line (BEOL) fabrication. The BEOL fabrication provides a power network and/or routing for circuitry of devices 100A-100C, correspondingly including macro regions 101A-101C and functional cell regions 102(1)-102(2).

FIG. 2A is a layout diagram of a functional cell region (CR) 202(1), in accordance with some embodiments.

Cell region 202(1) is an example of functional cell region 102(1) of FIG. 1A. In FIG. 2A: section line 5A-5A′ corresponds to cross-section 502A of FIG. 5A. Cell region 202(1) is arranged relative to the following: alpha tracks (or alpha lines) α00-α24 that extend parallel to the X-axis, and beta tracks (beta lines) β10-β14 that extend parallel to the Y-axis. For simplicity of illustration, not all of the beta tracks are shown in FIG. 2A.

In FIG. 2A, and in other layout diagrams disclosed herein, the first and second directions are assumed to be parallel correspondingly to the X-axis and the Y-axis. In some embodiments, the first and second directions are assumed to have orientations other than being parallel correspondingly to the X-axis and the Y-axis. In FIG. 2A, and in other layout diagrams disclosed herein, rows extend parallel to the X-axis.

A transistor-based device is comprised of cell regions which are representable by layout diagrams of which the layout diagram of FIG. 2A, and other layout diagrams disclosed herein, are examples. Regarding transistors, examples which comprise a transistor-based device include field effect transistors (FETs). An example of an architecture for a transistor-based device is complementary metal-oxide-semiconductor (CMOS) architecture. In a CMOS architecture, the FETs include negative-channel metal-oxide semiconductor (NMOS) FETs (NFETs) and positive-channel metal-oxide semiconductor (PMOS) FETS (PFETs). Regarding CMOS architecture, examples of FET architectures include planar field-effect transistor (FET) architecture, finFET architecture, gate-all-around FET (GAAFET) architectures, or the like. Examples of the GAAFET architecture include as nanowire architecture, nanosheet architecture, forksheet architecture, or the like.

Structures in a transistor-based device are represented by patterns (also known as shapes) in the layout diagram. For simplicity of discussion, elements in the layout diagrams of FIG. 2A and other layout diagrams disclosed herein will be referred to as if they are structures rather than patterns. For example, shapes in FIG. 2A representing instances of gate segments are referred to as gate segments per se rather than as gate shapes.

A layout diagram is a top view. Shapes in the layout diagram are two-dimensional relative to, e.g., the X-axis and the Y-axis, whereas the device being represented is three-dimensional. As such, a shape in such layout diagrams is described as having a width/length relative to the X-axis and a height relative to the Y-axis. Relative to the Z-axis, e.g., a bottom/back side of a first component being represented in the layout diagram is stacked on a top/front side of a second component device being represented in the layout diagram, or a top/front back side of the first component is stacked, e.g., under a bottom/back side of the second component.

Typically, relative to the Z-axis, the device is organized as a stack of layers in which are located corresponding structures, i.e., to which belong corresponding structures. Each shape in the layout diagram represents, more particularly, a component in a corresponding layer of the corresponding device. Also, typically, the layout diagram represents relative depth, i.e., positions along the Z-axis, of shapes and corresponding layers by superimposing a second shape on a first shape so that the second shape at least partially overlaps the first shape. For simplicity of illustration, some structures which have a first order of stacking along the Z-axis in the device are represented in the layout diagram using a second order of stacking along the Z-axis, i.e., a different/distorted stacking order.

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding device are represented, i.e., selected layers of the layout diagram are omitted, e.g., for simplicity of illustration. Alternatively, and/or additionally, in some circumstances, not all elements of a given depicted layer of the corresponding device are represented, i.e., selected elements of the given depicted layer of the layout diagram are omitted, e.g., for simplicity of illustration. The layout diagrams disclosed herein are examples of layout diagrams in which selected layers and/or selected elements of depicted given layers, have been omitted.

Depending upon the numbering convention of the corresponding process technology node by which a device is to be fabricated, on a front side of the device the first layer metallization is either metallization layer zero (MET0) or metallization layer one (MET1), and correspondingly a first interconnection layer on the first metallization layer is either interconnection layer zero (VIA0) or interconnection layer one (VIA1). In such embodiments, again depending upon the numbering convention of the corresponding process technology node, on a back side (not shown) of the device, the first buried metallization layer is either buried metallization layer zero (BMET0) or buried metallization layer one (BMET1), and correspondingly a first buried interconnection layer under the first metallization layer is either interconnection layer zero (VIA0) or interconnection layer one (VIA1).

In general regarding the figures disclosed herein (unless noted otherwise), the following nomenclature is adopted regarding the front side of a device: the first metallization layer is assumed to be MET0; the first interconnection layer is assumed to be VIA0; the second metallization layer is assumed to be MET1; the second interconnection layer is assumed to be VIA1; and the third metallization layer is assumed to MET2. Metallization segments in layer MET0 are referred to as M0 segments. Via structures in layer VIA0 are referred to as V0 structures. Metallization segments in layer MET1 are referred to as M1 segments. Via structures in layer VIA1 are referred to as V1 structures. Metallization segments in layer MET2 are referred to as M2 segments.

In general, regarding the figures disclosed herein (unless noted otherwise), or the like, the following nomenclature is adopted regarding the back side of a device: the first buried metallization layer is assumed to be BMET0; the first buried interconnection layer is assumed to be BVIA0; the second buried metallization layer is assumed to be BMET1; the second buried interconnection layer is assumed to be BVIA1; and the third buried metallization layer is assumed to BMET2. Metallization segments in layer BMET0 are referred to as buried M0 (BM0) segments. Via structures in layer BVIAO are referred to as BVO structures. Metallization segments in layer BMET1 are referred to as buried M1 (BM1) segments. Via structures in layer BVIA1 are referred to as BV1 structures. Metallization segments in layer BMET2 are referred to as buried M2 (BM2) segments.

In FIG. 2A, cell region 202(1) includes: a negative-type (N-type) active region 208N(1) that extends substantially parallel to the X-axis and is used for corresponding NFETs; an N-type well (N-well) (see FIG. 5A); a positive-type (P-type) active region 208P(1) that extends substantially parallel to the X-axis, is in the N-well, and is used for corresponding PFETs; gate segments 210(1)-210(2) that extend substantially parallel to the Y-axis; dummy gate segments 212(1)-212(2) that extend substantially parallel to the Y-axis; metal-to-source/drain contact (MD) structures 214 that extend substantially parallel to the Y-axis; cut-gate (CG) shapes 216 that extend parallel to the X-axis; and cut-MD (CMD) shapes 217 that extend parallel to the X-axis. Gate segments 210(1)-210(2) are co-track aligned to beta track 12. Dummy gate segments 212(1) and 212(2) are correspondingly aligned to beta tracks β10 and β14. MD structures 214 are aligned to corresponding ones of the beta tracks (not shown).

In some embodiments, a dummy gate segment (e.g., 212(1)-212(2)) is a gate segment that is not coupled to voltage source. In some embodiments, a dummy gate segment is a gate segment that is not coupled to a voltage source, e.g., VDD, VSS or the like. In some embodiments, a dummy gate segment is an isolation dummy gate (IDG) structure. In some embodiments, an isolation dummy gate (IDG) structure is a dielectric structure that includes one or more dielectric materials and functions as an electrical isolation structure. Accordingly, an IDG structure is not a structure that is electrically conductive and thus does not function, e.g., as an active gate of a transistor. An IDG structure includes one or more dielectric materials and functions as an electrical isolation structure. In some embodiments, an IDG structure is based on a gate segment as a precursor. In some embodiments, an IDG structure is based on a dummy gate structure. In some embodiments, a dummy gate structure includes a gate segment that is decoupled so as to not function, e.g., as a gate of a transistor, a gate-insulator layer, (optionally) one or more spacers, or the like. In some embodiments, an IDG structure is formed by first forming a gate segment e.g., which is included in a dummy gate structure, sacrificing/removing (e.g., etching) the gate segment to form a trench, (optionally) removing a portion of a substrate that previously had been under or over or around the gate segment to deepen the trench, and then filling the trench with one or more dielectric materials such that the physical dimensions of the resultant electrical isolation structure, i.e., the IDG, are similar to the dimensions of the gate segment which was sacrificed. In some embodiments, an IDG is a dielectric feature that includes one or more dielectric materials (e.g., oxide, nitride, oxynitride, or other suitable materials), and functions as an isolation feature. In some embodiments, an IDG is a continuous polysilicon on oxide diffusion (OD) edge structure, and is referred to as a CPODE structure.

Each of gate segments 210(1)-210(2), dummy gate segments 212(1)-212(2) and MD structures 214 correspondingly overlap active regions 208N(1) and 208P(1). Where a part of one of MD structures 214 overlaps an active region (e.g., active regions 208N(1) and 208P(1)), the correspondingly overlapped sub-region of the active region is relatively more heavily doped to serve as a source/drain (S/D) region of a corresponding transistor. Where a part of one of gate segments 210(1)-210(2) overlaps an active region (e.g., active regions 208N(1) and 208P(1)), the correspondingly overlapped sub-region of the active region is configured to serve as a channel region of a corresponding transistor. As such, the gate-segment-overlapped sub-region of the active region is free from being relatively more heavily doped as compared, e.g., to an S/D region.

In some embodiments, each instance of CG shape 216 represents a dielectric structure that replaces the portion of the corresponding gate segment which is overlapped by the instance of CG shape 216. In some embodiments, dielectric structures 216 are formed of a dielectric material (e.g., a dielectric material) that is different than interstitial material (not shown) which fills interstitial space around dielectric structures 216, e.g., the interstitial material is another dielectric material. In some embodiments, dielectric structures 216 are formed of a nitride material whereas the interstitial material is an oxide, or vice versa. In some embodiments, dielectric structures 216 are formed of a material that is the same as the interstitial material such that dielectric structures 216 are more easily discerned (or identified) in the corresponding layout diagram than in the device manufactured according to the layout diagram. In some embodiments, dielectric structures 216 are referred to as cut-gate (CG) structures.

In some embodiments, dielectric structures 216 are described as byproducts of trimming the lengths of the precursors of gate segments, e.g., 210(1) and 210(2). Relative to the Y-axis, a height of each of dielectric structures 216 varies in order to achieve an overhang distance D_G_ovhmin for the corresponding end of the corresponding gate segment as set by one or more design rules of a corresponding semiconductor process technology node. In general, relative to the Y-axis, the width of dielectric structures 216 is inversely proportional to the width of the corresponding AR-portion. Width W_CG_min is a minimum width for such dielectric structures (e.g., 216) as set by one or more design rules of a corresponding semiconductor process technology node.

In some embodiments, each instance of CMD shape 217 represents a dielectric structure that replaces the portion of the corresponding MD structure which is overlapped by the instance of CMD shape 217. In some embodiments, dielectric structures 217 are formed of a dielectric material (e.g., a dielectric material) that is different than interstitial material (not shown) which fills interstitial space around dielectric structures 217, e.g., the interstitial material is another dielectric material. In some embodiments, dielectric structures 217 are formed of a nitride material whereas the interstitial material is an oxide, or vice versa. In some embodiments, dielectric structures 217 are formed of a material that is the same as the interstitial material such that dielectric structures 217 are more easily discerned (or identified) in the corresponding layout diagram than in the device manufactured according to the layout diagram. In some embodiments, dielectric structures 217 are referred to as cut-gate (CG) structures.

In some embodiments, dielectric structures 217 are described as byproducts of trimming the lengths of the precursors of MD structures, e.g., 214. Relative to the Y-axis, a height of each of dielectric structures 217 varies in order to achieve an overhang distance D_MD_ovhmin for the corresponding end of the corresponding gate segment as set by one or more design rules of a corresponding semiconductor process technology node. In general, relative to the Y-axis, the width of dielectric structures 217 is inversely proportional to the width of the corresponding AR-portion. Width W_CMD_min is a minimum width for dielectric such structures (e.g., 217) as set by one or more design rules of a corresponding semiconductor process technology node.

Cell region 202(1) is substantially rectangular. Relative to the Y-axis, cell region 202(1) has top 220(1) and bottom 222(1) boundaries that are substantially parallel to each other. Relative to the X-axis, cell region 202(1) has left and right boundaries that are: substantially parallel to each other; correspondingly aligned to beta tracks β10 and β14; and correspondingly aligned to dummy gate segments 212(1) and 212(2). Each of active regions 208N(1) and 208P(1): is substantially rectangular; substantially extends from the left boundary to the right boundary of cell region 202(1) such that active regions 208N(1) and 208P(1) have substantially the same length relative to the X-axis; and has substantially the same width relative to the Y-axis.

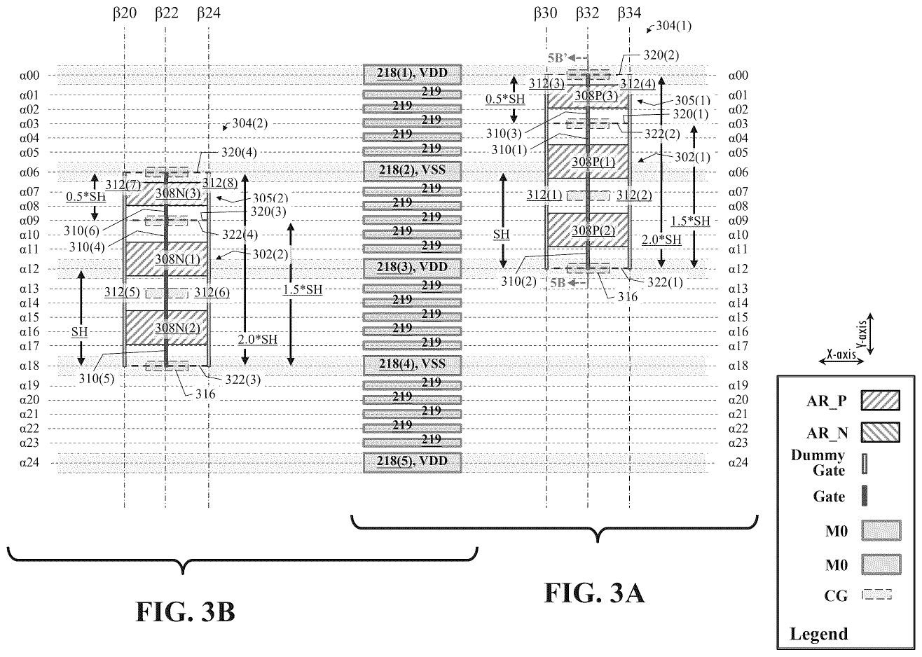

In FIG. 2A, first metallization layer MET0 overlies gate segments 210(1)-210(2), dummy gate segments 212(1)-212(2) and MD structures 214. For simplicity of illustration, the M0 segments in FIG. 2A are not shown as extending horizontally over gate segments 210(1)-210(2), dummy gate segments 212(1)-212(2) and MD structures 214 though it is to be understood that the M0 segments in FIG. 2A do extend horizontally over gate segments 210(1)-210(2), dummy gate segments 212(1)-212(2) and MD structures 214. FIGS. 2B-2E and 3A-3B depict M0 segments in a manner similar to FIG. 2A.

Layer MET0 includes M0 segments. The M0 segments include power grid (PG) segments (M0_PG segments) 218(1)-218(5) and routing (RTE) segments (M0_RTE segments) 219 that are correspondingly aligned to alpha tracks α00-α24. In particular, M0_PG segments 218(1)-218(5) are correspondingly aligned to alpha tracks α00, α06, α12, α18 and α24. In FIG. 2A, and likewise in FIGS. 2B-2E and 3A-3B: M0_PG segments 218(1), 218(3) and 218(5) are configured for a first reference voltage, e.g., VDD; and M0_PG segments 218(2) and 218(4) are configured for a second reference voltage, e.g., VSS. M0_PG segments 218(2)-218(4) have a pitch p_218. Between adjacent ones of M0_PG segments 218(2)-218(4), instances of M0_RTE segment 219 have a pitch p_219, where pitch p_219 is less than pitch p_218 such that pitch p_219<pitch p_218.

In cell region 202(1), M0_PG segment 218(2) substantially overlaps active region 208N(1). In the example of FIG. 2A, M0_PG segment 218(2) substantially asymmetrically overlaps active region 208N(1). Active region 208P(1) is free from being overlapped by an M0_PG segment, e.g., is free from being overlapped by any of M0_PG segments 218(1)-218(5). Bottom boundary 222(1) of cell region 202(1) is overlapped by M0_PG segment 218(3). M0_PG segment 218(3) is adjacent to active region 208P(1) and is free from overlapping an active region, e.g., is free from overlapping active regions 208N(1) or 208P(1).

In FIG. 2A: an instance of dielectric structure 216 is aligned to alpha track α03 and is abutted to an upper end of gate segment 210(1); an instance of dielectric structure 216 is aligned to alpha track α12 and is abutted to a lower end of gate segment 210(2); an instance of dielectric structure 217 is aligned to alpha track α03 and is abutted to an upper end of a corresponding instance of MD structure 214, the corresponding instance of MD structure 214 being (i) over active region 208N(1) and (ii) aligned to beta track β13 (not shown), where beta track β13 is between beta tracks β12 and β14; an instance of dielectric structure 217 is aligned to alpha track α12 and is abutted to a lower end of a corresponding instance of MD structure 214, the corresponding instance of MD structure 214 being (i) over active region 208P(1) and (ii) aligned to beta track β13; an instance of dielectric structure 217 is aligned to alpha track α03 and is abutted to an upper end of a corresponding instance of MD structure 214, the corresponding instance of MD structure 214 being (i) over active region 208N(1) and (ii) aligned to beta track β11 (not shown), where beta track β11 is between beta tracks β10 and β12; and an instance of dielectric structure 217 is aligned to alpha track α12 and is abutted to a lower end of a corresponding instance of MD structure 214, the corresponding instance of MD structure 214 being is (i) over active region 208P(1) and (ii) aligned to beta track β11.

In some embodiments, regarding cell region 202(1): an instance of dielectric structure 216 is in the central area of cell region 202(1), i.e., is aligned to beta track 12 is proximal to or overlaps alpha track α07, and is substantially equidistant between active regions 208N(1) and 208P(1); an instance of dielectric structure 217 is in the central area of cell region 202(1), i.e., is aligned to beta track β13, is proximal to or overlaps alpha track α07, and is substantially equidistant between active regions 208N(1) and 208P(1); and an instance of dielectric structure 217 is in the central area of cell region 202(1), i.e., is aligned to beta track β11, is proximal to or overlaps alpha track α07, and is substantially equidistant between active regions 208N(1) and 208P(1).

For cell region 202(1), top 220(1) and bottom 222(1) boundaries correspondingly align to alpha tracks α03 and α12. Top boundary 220(1) is between active region 208N(1) and M0_PG segment 218(1). Top boundary 220(1) of cell region 202(1) is free from being overlapped by an M0_PG segment, e.g., is free from being overlapped by any of M0_PG segments 218(1)-218(5). Top boundary 220(1) of cell region 202(1) is free from being overlapped by an active region, e.g., is free from overlapping active regions 208N(1) or 208P(1).

In some embodiments, a cell region in a semiconductor device based on a layout diagram (e.g., FIG. 2A) is referred to as a fabricated cell region. In some embodiments, top and bottom boundaries of a fabricated cell region (e.g., corresponding to cell region 202(1)) are recognizable as intersecting corresponding instances of dielectric structure 216. In some embodiments, top and bottom boundaries of a fabricated cell region (e.g., corresponding to cell region 202(1)) are recognizable as intersecting corresponding instances of dielectric structure 217.

In some embodiments, top and bottom boundaries of a fabricated cell region (e.g., corresponding to cell region 202(1)) are recognizable as follows: a CMOS-pair of an N-type active region (e.g., 208N(1)) and adjacent P-type active region (e.g., 208P(1)) which are adjacent in the second direction (e.g., parallel to the Y-axis) are identified in the fabricated cell region; a first reference line is identified in the fabricated cell region, where the first reference line extends in the first direction (e.g., parallel to the X-axis) and is adjacent the upper active region (e.g., 208N(1)) of the CMOS-pair, and where the first reference line intersects the instance of dielectric structure 216 and the instances of dielectric structure 217 that are aligned to alpha track α03 in FIG. 3A; a second reference line is identified in the fabricated cell region, where the second reference line extends in the first direction and is adjacent the lower active region (e.g., 208P(1)) of the CMOS-pair, and where the second reference line intersects the instance of dielectric structure 216 and the instances of dielectric structure 217 that are aligned to alpha track α12 in FIG. 3A; the top boundary (e.g., 220(1) of the fabricated cell region is regarded as being the first reference line; and the bottom boundary (e.g., 222(1) of the fabricated cell region is regarded as being the second reference line. More generally, top and bottom boundaries of a fabricated cell regions corresponding to other cell region regions disclosed herein are recognizable in a manner similar to the manner described regarding a fabricated cell region corresponding to cell region 202(1) of FIG. 3A.

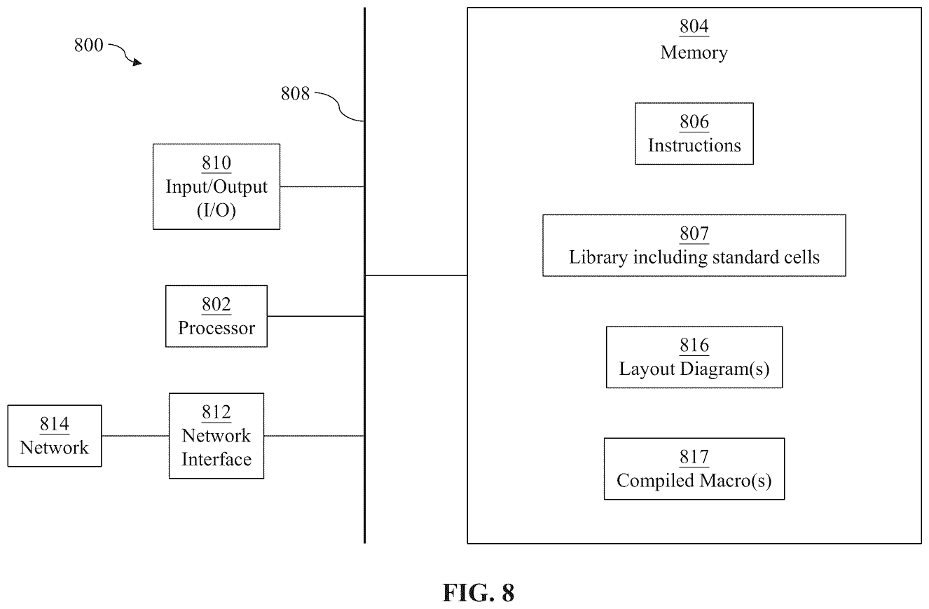

In some embodiments, having a top and/or bottom boundary overlapped by an M0_PG segment, e.g., bottom boundary 222(1) overlapped by M0_PG segment 218(3), facilitates automatic placement and routing (APR) (see FIG. 8).

In some embodiments, the instance of CG shape 216 in the central area of cell region 202(1) is omitted such that gate segments 210(1) and 210(2) represent corresponding portions of a longer gate segment. In some embodiments, the instance of CG shape 216 that overlaps top boundary 220(1) of cell region 202(1) is omitted such that gate segment 210(1) represents a portion of a longer gate segment (not shown). In some embodiments, the instance of CG shape 216 that overlaps bottom boundary 222(1) of cell region 202(1) is omitted such that gate segment 210(2) represents a portion of a longer gate segment (not shown).

In some embodiments, the instance of CMD shape 217 adjacent to dummy gate segment 212(1) in the central area of cell region 202(1) is omitted such that the two otherwise-separate yet corresponding co-beta-track aligned MD structures represent corresponding portions of a longer MD structure. In some embodiments, the instance of CMD shape 217 adjacent to dummy gate segment 212(2) in the central area of cell region 202(1) is omitted such that the two otherwise-separate yet corresponding co-beta-track aligned MD structures represent corresponding portions of a longer MD structure. In some embodiments, the instance of CMD shape 217 adjacent to dummy gate segment 212(1) that overlaps top boundary 220(1) of cell region 202(1) is omitted such that corresponding MD structure 214 represents a portion of a longer MD structure (not shown). In some embodiments, the instance of CMD shape 217 adjacent to dummy gate segment 212(2) that overlaps top boundary 220(1) of cell region 202(1) is omitted such that the corresponding MD structure 214 represents a portion of a longer MD structure (not shown). In some embodiments, the instance of CMD shape 217 adjacent to dummy gate segment 212(1) that overlaps bottom boundary 222(1) of cell region 202(1) is omitted such that the corresponding MD structure 214 represents a portion of a longer MD structure (not shown). In some embodiments, the instance of CMD shape 217 adjacent to dummy gate segment 212(2) that overlaps bottom boundary 222(1) of cell region 202(1) is omitted such that the corresponding MD structure 214 represents a portion of a longer MD structure (not shown).

In some embodiments, relative to the X-axis: cell region 202(1) is left-adjacent to or leftward abuts another cell region (see FIG. 4C), e.g., another instance of cell region 202(1) or a different cell region; and/or cell region 202(1) is right-adjacent to or rightward abuts another cell region (see FIG. 4C), e.g., another instance of cell region 202(1) or a different cell region.

Relative to the Y-axis, cell region 202(1) has a height of about 1.5*SH, i.e., has a height that is about a 1.5 multiple of the height SH of a single height cell region (see. e.g., instances of cell region 436 of FIG. 4C, instances of cell region 436 of FIG. 4D, or the like), where height SH of the single height cell region is determined according to one or more design rules of a corresponding semiconductor process technology node. In FIG. 2A, pitch p_218 is equal to height SH such that p_218=SH. The single height cell region is substantially rectangular and includes two active regions, e.g. one P-type and one N-type. Each of the active regions in the single height cell region: is substantially rectangular; substantially extends from a left boundary to a right boundary of the single height cell region such that active regions of the single height cell region have substantially the same length relative to the X-axis; and has substantially the same width W_AR_min relative to the Y-axis. Relative to the Y-axis, width W_ARmin of the active regions in the single height cell region is a minimum width of an active region according to one or more design rules of a corresponding semiconductor process technology node. In some embodiments, relative to the Y-axis, a width of the M0_PG segments (e.g., 218(1)-218(5), W_218, is about an 0.96 multiple of W_AR_min such that W_218≈0.96*W_AR_min. In some embodiments, cell region 202(1) is referred to as a one-and-one-half height cell region. In some embodiments, cell region 202(1) is referred to as a three-halves half height cell region.

Relative to the Y-axis, active regions 208N(1) and 208P(1) of cell region 202(1) have substantially the same height W_AR_2A. In some embodiments, W_AR1≈1.4*W_AR_min. In some embodiments, 0.71*W_AR_2A≈W_AR_min.

According to a first other approach, two single height cell regions are stacked on each other relative to the Y-axis (in a two-stack arrangement) which represents a counterpart to cell region 202(1). The counterpart two-stack has: the same width as cell region 202(1); a net height of 2.0*SH; a P-type active region density of 2*d_ARP_SH, where d_ARP_SH is the P-type active region density of the single height cell region; and an N-type active region density of 2*d_ARN_SH, where d_ARP_SH is the P-type active region density of the single height cell region, and where d_ARN_SH≈d_ARP_SH. As compared to the counterpart two-stack, cell region 202(1) has: a density of P-type active region d_ARP_2A≈1.87*d_AR_SH despite having a relatively shorter height of 1.5*SH; and a density of N-type active region d_ARN_2A≈1.87*d_AR_SH despite having a relatively shorter height of 1.5*SH. In some embodiments, relative to the Y-axis, active region 208N(1) is not as wide as active region 208P(1) in cell region 202(1). In some of such embodiments, as compared to the counterpart two-stack, cell region 202(1) has: a density of P-type active region d_ARP_2A≈1.87*d_AR_SH despite having a relatively shorter height of 1.5*SH; and a density of N-type active region d_ARN_2A=0.94*d_AR_SH.

FIG. 2B is a layout diagram of a functional cell region 202(2), in accordance with some embodiments.

Cell region 202(2) of FIG. 2B is similar to cell region 202(1) of FIG. 2A. For purposes of brevity, the discussion will focus on differences of cell region 202(2) as compared to cell region 202(1) rather than on similarities. In general, the doping of the active regions in FIG. 2B is reversed as compared to the doping of the active regions in FIG. 2A.

In FIG. 2B, cell region 202(2) includes: an N-type active region 208N(2); an N-well (see FIG. 5A); a P-type active region 208P(2) in the N-well; gate segments 210(3)-210(4); dummy gate segments 212(3)-212(4); MD structures 214; CG shapes 216; and CMD shapes 217. Gate segments 210(3)-210(4) are co-track aligned to beta track 302. Dummy gate segments 212(3) and 212(4) are correspondingly aligned to beta tracks 00 and β04.

In cell region 202(2), each of gate segments 210(3)-210(4), dummy gate segments 212(3)-212(4) and MD structures 214 correspondingly overlap active regions 208N(2) and 208P(2). Cell region 202(2) has left and right boundaries that are (i) correspondingly aligned to beta tracks β00 and β04 and (ii) correspondingly aligned to dummy gate segments 212(3) and 212(4).

For cell region 202(2), top 220(2) and bottom 222(2) boundaries of cell region 202(2) correspondingly align to alpha tracks α09 and α18. Top boundary 220(2) is between active region 208P(2) and M0_PG segment 218(2). Top boundary 220(2) of cell region 202(2) is free from being overlapped by an M0_PG segment, e.g., is free from being overlapped by any of M0_PG segments 218(1)-218(5). Top boundary 220(2) of cell region 202(2) is free from being overlapped by an active region, e.g., is free from overlapping active regions 208N(2) or 208P(2).

In cell region 202(1), M0_PG segment 218(3) substantially overlaps active region 208P(2). In the example of FIG. 2B, M0_PG segment 218(3) substantially asymmetrically overlaps active region 208P(2). Active region 208N(2) is free from being overlapped by an M0_PG segment, e.g., is free from being overlapped by any of M0_PG segments 218(1)-218(5). Bottom boundary 222(2) of cell region 202(2) is overlapped by M0_PG segment 218(4). In some embodiments, having a top and/or bottom boundary overlapped by an M0_PG segment, e.g., bottom boundary 222(2) overlapped by M0_PG segment 218(4), facilitates APR (see FIG. 8). M0_PG segment 218(4) is adjacent to active region 208N(2) and is free from overlapping an active region, e.g., is free from overlapping active regions 208N(2) or 208P(2).

FIG. 2C is a layout diagram of stacked functional cell regions 202(1) and 202(3), in accordance with some embodiments.

Cell region 202(3) of FIG. 2C is similar to cell region 202(1) of FIGS. 2A and 2C. For purposes of brevity, the discussion will focus on differences of cell region 202(3) as compared to cell region 202(1) rather than on similarities. Relative to the Y-axis, cell region 202(1) is stacked on cell region 202(3). A stack of two cell regions is referred to herein as a two-stack; as such, cell region 202(1) stacked on cell region 202(3) is referred to herein as two-stack 203(1). Cell region 202(1) is arranged relative to alpha tracks α00-α30. In general, cell region 202(3) is a version of cell region 202(1). More specifically, relative to an axis of symmetry represented by alpha track α12, cell region 202(3) is mirror symmetric with respect to cell region 202(1). In FIG. 2C, each of cell regions 202(1) and 202(3) is aligned to beta tracks β10-β14.

Relative to the Y-axis, cell regions 202(1) and 202(3) combined (together) as two-stack 203(1) have a height of about 2*(1.5*SH)=3.0*SH, i.e., have about a 3.0 multiple of the height SH of the single height cell region (see. e.g., instances of cell region 436 of FIG. 4C, instances of cell region 436 of FIG. 4D, or the like). Again, height SH is the height of the single height cell region.

In FIG. 2C, cell region 202(3) includes: an N-type active region 208N(3); an N-well (see FIG. 5A); a P-type active region 208P(3) in the N-well; gate segments 210(5)-210(6); dummy gate segments 212(5)-212(6); MD structures (not shown in FIG. 2C but see FIG. 2A); CG shapes 216; CMD shapes (not shown in FIG. 2C but see FIG. 2A); M0_PG segment 218(6) as well as M0_PG segments 218(1)-218(5); and additional instances of M0_RTE segments 219. Gate segments 210(5)-210(6) of cell region 202(3) are co-track aligned to beta track 312 as are gate segments 210(1)-210(2) of cell region 202(1). Dummy gate segments 212(5) and 212(6) of cell region 202(3) are correspondingly aligned to beta tracks β10 and β14 as are dummy gate segments 212(1) and 212(2) of cell region 202(1). In FIG. 2C, and likewise in FIGS. 2D-2E: M0_PG segment 218(6) is configured for the second reference voltage, e.g., VSS.

In cell region 202(3), each of gate segments 210(5)-210(6), dummy gate segments 212(5)-212(6) and corresponding ones of the MD structures correspondingly overlap active regions 208N(3) and 208P(3). Cell region 202(3) has left and right boundaries that are correspondingly aligned to beta tracks β10 and β14 as are left and right boundaries of cell region 202(1). Dummy gate segments 212(5) and 212(6) are correspondingly aligned to beta tracks β10 and β14 as are dummy gate segments 212(1) and 212(2) of cell region 202(1).

For cell region 202(3), top 220(3) and bottom 222(3) boundaries correspondingly align to alpha tracks α12 and α21. As cell region 202(3) is stacked under cell region 202(1), top boundary 220(3) of cell region 202(3) is the same as bottom boundary 222(1) of cell region 202(1). Each of top boundary 220(3) of cell region 202(3) and bottom boundary 222(1) of cell region 202(1) is overlapped by M0_PG segment 218(3). In some embodiments, having a top or bottom boundary, e.g., 220(3) and 222(1), overlapped by an M0_PG segment, e.g., 218(3), facilitates APR (see FIG. 8). M0_PG segment 218(3) is (i) adjacent to each of active region 208P(1) and 208P(3) and (ii) is free from overlapping an active region, e.g., is free from overlapping active regions 208N(1), 208N(3), 208P(1) or 208P(3).

For cell region 202(3), bottom boundary 222(3) is between active region 208N(3) and M0_PG segment 218(5). Bottom boundary 222(3) of cell region 202(3) is free from being overlapped by an M0_PG segment, e.g., is free from being overlapped by any of M0_PG segments 218(1)-218(6). Bottom boundary 222(3) of cell region 202(3) is free from being overlapped by an active region, e.g., is free from overlapping active regions 208N(1), 208N(3), 208P(1) or 208P(3). M0_PG segment 218(4) substantially overlaps active region 208N(3). In the example of FIG. 2C, M0_PG segment 218(4) substantially asymmetrically overlaps active region 208N(3). Active region 208P(3) is free from being overlapped by an M0_PG segment, e.g., is free from being overlapped by any of M0_PG segments 218(1)-218(6).

FIG. 2D is a layout diagram of stacked functional cell regions 202(2) and 202(4), in accordance with some embodiments.

Cell region 202(4) of FIG. 2D is similar to cell region 202(2) of FIGS. 2B and 2D. For purposes of brevity, the discussion will focus on differences of cell region 202(4) as compared to cell region 202(2) rather than on similarities. Relative to the Y-axis, cell region 202(2) is stacked on cell region 202(4) and together represents a two-stack 203(2). Cell region 202(4) is arranged relative to alpha tracks α00-α30. In general, cell region 202(4) is a version of cell region 202(2). More specifically, relative to an axis of symmetry represented by alpha track α18, cell region 202(4) is mirror symmetric with respect to cell region 202(2). In FIG. 2D, each of cell regions 202(2) and 202(4) is aligned to beta tracks β00-β04.

Relative to the Y-axis, cell regions 202(2) and 202(4) combined (together) as two-stack 203(2) have a height of about 2*(1.5*SH)=3.0*SH, i.e., have about a 3.0 multiple of the height SH of the single height cell region (see. e.g., instances of cell region 436 of FIG. 4C, instances of cell region 436 of FIG. 4D, or the like). Again, height SH is the height of the single height cell region.

In FIG. 2D, cell region 202(4) includes: an N-type active region 208N(4); an N-well (see FIG. 5A); a P-type active region 208P(4) in the N-well; gate segments 210(7)-210(8); dummy gate segments 212(7)-212(8); MD structures (not shown in FIG. 2D but see FIG. 2A); CG shapes 216; and CMD shapes (not shown in FIG. 2D but see FIG. 2A); M0_PG segment 218(6) as well as M0_PG segments 218(1)-218(5); and additional instances of M0_RTE segments 219. Gate segments 210(7)-210(8) of cell region 202(4) are co-track aligned to beta track β02 as are gate segments 210(3)-210(4) of cell region 202(2). Dummy gate segments 212(7) and 212(8) of cell region 202(4) are correspondingly aligned to beta tracks 00 and 304 as are dummy gate segments 212(3) and 212(4) of cell region 202(2).

In cell region 202(4), each of gate segments 210(7)-210(8), dummy gate segments 212(7)-212(8) and corresponding ones of the MD structures correspondingly overlap active regions 208N(4) and 208P(4). Cell region 202(4) has left and right boundaries that are correspondingly aligned to beta tracks β00 and β04 as are left and right boundaries of cell region 202(2). Dummy gate segments 212(7) and 212(8) are correspondingly aligned to beta tracks β00 and β04 as are dummy gate segments 212(3) and 212(4) of cell region 202(2).

For cell region 202(4), top 220(4) and bottom 222(4) boundaries correspondingly align to alpha tracks α18 and α27. As cell region 202(4) is stacked under cell region 202(2), top boundary 220(4) of cell region 202(4) is the same as bottom boundary 222(2) of cell region 202(2). Each of top boundary 220(4) of cell region 202(4) and bottom boundary 222(2) of cell region 202(2) is overlapped by M0_PG segment 218(4). In some embodiments, having a top and/or bottom boundary overlapped by an M0_PG segment, e.g., top boundary 222(2) and bottom boundary 220(4) overlapped by an M0_PG segment 218(4), facilitates APR (see FIG. 8). M0_PG segment 218(4) is (i) adjacent to each of active region 208N(2) and 208N(4) and (ii) is free from overlapping an active region, e.g., is free from overlapping active regions 208N(2), 208N(4), 208P(2) or 208P(4).

In cell region 202(4), bottom boundary 222(4) is between active region 208P(43) and M0_PG segment 218(6). Bottom boundary 222(4) of cell region 202(4) is free from being overlapped by an M0_PG segment, e.g., is free from being overlapped by any of M0_PG segments 218(1)-218(6). Bottom boundary 222(4) of cell region 202(4) is free from being overlapped by an active region, e.g., is free from overlapping active regions 208N(2), 208N(4), 208P(2) or 208P(4). M0_PG segment 218(5) substantially overlaps active region 208P(4). In the example of FIG. 2D, M0_PG segment 218(5) substantially asymmetrically overlaps active region 208P(4). Active region 208N(4) is free from being overlapped by an M0_PG segment, e.g., is free from being overlapped by any of M0_PG segments 218(1)-218(6).

FIG. 2E is a layout diagram of stacked functional cell regions 202(5) and 202(6), in accordance with some embodiments.

Cell regions 202(5) and 202(6) of FIG. 2E correspondingly are similar to cell regions 202(1) and 202(3) of FIG. 2C. For purposes of brevity, the discussion will focus on differences of 202(5) and 202(6) as compared to cell regions 202(1) and 202(3) rather than on similarities.

In general, cell region 202(5) is a non-CMOS version of cell region 202(1), and cell region 202(6) is a non-CMOS version of cell region 202(3). More specifically, active region 208P(5) of cell region 202(5) replaces active region 208N(1) of cell region 202(1) while active region 208P(6) of cell region 202(5) corresponds to active region 208P(1) of cell region 202(1). Also, active region 208P(8) of cell region 202(6) replaces active region 208N(3) of cell region 202(3) while active region 208P(7) of cell region 202(6) corresponds to active region 208P(3) of cell region 202(1). Cell region 202(5) is stacked on cell region 202(6) and together represent a two-stack 203(3). In some embodiments, cell region 202(5) and/or cell region 202(6) and/or the stacked combination thereof is/are used in a header circuit (see, e.g., FIG. 4A).

FIG. 2F is a layout diagram of stacked functional cell regions 202(7) and 202(8), in accordance with some embodiments.

Cell regions 202(7) and 202(8) of FIG. 2F correspondingly are similar to cell regions 202(2) and 202(4) of FIG. 2D. For purposes of brevity, the discussion will focus on differences of 202(7) and 202(8) as compared to cell regions 202(2) and 202(4) rather than on similarities.

In general, cell region 202(7) is a non-CMOS version of cell region 202(2), and cell region 202(8) is a non-CMOS version of cell region 202(4). More specifically, active region 208N(5) of cell region 202(7) replaces active region 208P(2) of cell region 202(2) while active region 208N(6) of cell region 202(6) corresponds to active region 208N(2) of cell region 202(2). Also, active region 208N(8) of cell region 202(8) replaces active region 208P(4) of cell region 202(4) while active region 208N(7) of cell region 202(8) corresponds to active region 208N(4) of cell region 202(2). Cell region 202(7) is stacked on cell region 202(8) and together represent a two-stack 203(4). In some embodiments, cell region 202(7) and/or cell region 202(8) and/or the stacked combination thereof is/are used in a footer circuit (see, e.g., FIG. 4B).

FIG. 3A is a layout diagram of a functional cell region 304(1), in accordance with some embodiments.

Cell region 304(1) includes a cell region 305(1) stacked on a cell region 302(1) relative to the Y-axis. In FIG. 3A: section line 5B-5B′ corresponds to cross-section 502B of FIG. 5B. Cell region 302(1) of FIG. 3A is similar to cell region 202(5) of FIG. 2E. For purposes of brevity, the discussion will focus on differences of cell region 302(1) as compared to cell region 202(5) rather than on similarities. In FIG. 3A, for simplicity of illustration, MD structures (see 214 FIGS. 2A-2B) and dielectric structures that are counterparts to dielectric structures 217 (see FIGS. 2A-2B).

Cell region 302(1) is a non-CMOS cell region. The active region of cell region 305(1) has the same dopant type as the active regions of cell region 302(1). Hence, cell region 304(1) is a non-CMOS cell region.

Cell region 304(1) is arranged relative to the following: alpha tracks (or alpha lines) α00-α24 that extend parallel to the X-axis, and beta tracks (beta lines) 30-034 that extend parallel to the Y-axis. For simplicity of illustration, not all of the beta tracks are shown in FIG. 3A. In FIG. 3A, each of cell regions 305(1) and 302(1) is aligned to beta tracks β3 -β34.

Cell region 304(1) includes: an N-well (see FIG. 5A); P-type active regions 308P(1)-308P(3) in the N-well; gate segments 310(1)-310(3); dummy gate segments 312(1)-312(4); MD structures (not shown in FIG. 3A but see FIG. 2A); CG shapes 216; CMD shapes (not shown in FIG. 3A but see FIG. 2A); M0_PG segments 218(1)-218(3) amongst M0_PG segments 218(1)-218(5); and instances of M0_RTE segments 219. Gate segments 310(1)-310(2) of cell region 302(1) and gate segment 310(3) of cell region 305(1) are co-track aligned to beta track 332. Dummy gate segments 312(1) and 312(2) of cell region 302(1) are correspondingly aligned to beta tracks β30 and β34 as are dummy gate segments 312(3) and 312(4) of cell region 305(1).

In cell region 302(1), each of gate segments 310(1)-310(2), dummy gate segments 312(1)-312(2) and corresponding ones of the MD structures correspondingly overlap active regions 308P(1) and 308P(2). In cell region 305(1), gate segment 310(3), dummy gate segments 312(3)-312(4) and corresponding ones of the MD structures correspondingly overlap active region 308P(3). Cell region 302(1) has left and right boundaries that are correspondingly aligned to beta tracks β30 and β34 as are left and right boundaries of cell region 305(1). Dummy gate segments 312(1) and 312(2) of cell region 302(1) are correspondingly aligned to beta tracks 30 and β34 as are dummy gate segments 312(3) and 312(4) of cell region 305(1).

For cell region 302(1), top 320(1) and bottom 322(1) boundaries correspondingly align to alpha tracks α03 and α12. For cell region 305(1), top 320(2) and bottom 322(2) boundaries correspondingly align to alpha tracks α00 and α03. As cell region 302(1) is stacked under cell region 305(1): top boundary 320(1) of cell region 302(1) is the same as bottom boundary 322(2) of cell region 305(1); and cell region 304(1) has top boundary 320(1) and bottom boundary 322(1).

In some embodiments, top and bottom boundaries of a fabricated cell region (e.g., corresponding to cell region 304(1)) are recognizable as intersecting corresponding instances of dielectric structure 316. In some embodiments, top and bottom boundaries of a fabricated cell region (e.g., corresponding to cell region 304(1)) are recognizable as intersecting corresponding instances of a dielectric structure (see 217), the latter resulting from having trimmed a corresponding MD structure (see 214).

In some embodiments, top and bottom boundaries of a fabricated cell region (e.g., corresponding to cell region 304(1)) are recognizable as follows: a PMOS-triplet of three P-type active region (e.g., 308P(1)-308P(3)) which are adjacent in the second direction (e.g., parallel to the Y-axis) are identified in the fabricated cell region;
a first reference line is identified in the fabricated cell region, where the first reference line extends in the first direction (e.g., parallel to the X-axis) and is adjacent the upper active region (e.g., 308P(3)) of the PMOS-triplet, and where the first reference line intersects a corresponding instance of dielectric structure 316 and instances of counterpart dielectric structures (not shown) that are aligned to alpha track α00 in FIG. 3A;
a second reference line is identified in the fabricated cell region, where the second reference line extends in the first direction and is adjacent the lower active region (e.g., 308P(2)) of the PMOS-triplet, and where the second reference line intersects an instance of dielectric structure 216 and instances of counterpart dielectric structures (not shown) that are aligned to alpha track α12 in FIG. 3A; the top boundary (e.g., 320(2)) of the fabricated cell region is regarded as being the first reference line; and the bottom boundary (e.g., 322(1)) of the fabricated cell region is regarded as being the second reference line.

In some embodiments, relative to the X-axis: cell region 304(1) is left-adjacent to or leftward abuts another cell region (see FIG. 4D), e.g., another instance of cell region 304(1) or a different cell region; and/or cell region 304(1) is right-adjacent to or rightward abuts another cell region (see FIG. 4D), e.g., another instance of cell region 304(1) or a different cell region.

Relative to the Y-axis, cell region 305(1) has a height of about 0.5*SH, i.e., has a height that is about a 0.5 multiple of the height SH of the single height cell region (see. e.g., instances of cell region 436 of FIG. 4C, instances of cell region 436 of FIG. 4D, or the like). In some embodiments, cell region 305(1) is referred to as a one-half height (or half-height) cell region. Relative to the Y-axis, active region 208P(3) has width W_AR_min. Like cell region 202(5) of FIG. 2E, cell region 302(1) has a height of about 1.5*SH. Relative to the Y-axis, cell regions 305(1) and 302(1) combined (together) as cell region 304(1) have a height of about 2.0*SH, i.e., have about a 2.0 multiple of the height SH of the single height cell region. In some embodiments, cell region 304(1) is referred to as a double height cell region. In some embodiments, cell region 304(1) is used in a header circuit (see, e.g., FIG. 4A).

In FIG. 3A, top boundary 320(1) of cell region 302(1) is between active regions 308P(1) and 308P(3). Top boundary 320(1) of cell region 302(1) is free from being overlapped by an M0_PG segment, e.g., is free from being overlapped by any of M0_PG segments 218(1)-218(5). Top boundary 320(1) of cell region 302(1) is free from being overlapped by an active region, e.g., is free from overlapping active regions 308P(1)-308P(3). Bottom boundary 322(1) of cell region 302(1) is adjacent active region 308P(2). Bottom boundary 322(1) of cell region 302(1) is overlapped by M0_PG segment 218(3). In some embodiments, having a top and/or bottom boundary, e.g., bottom boundary 322(1), overlapped by an M0_PG segment, e.g., 218(3) facilitates APR (see FIG. 8). Bottom boundary 322(1) of cell region 302(1) is free from being overlapped by an active region, e.g., is free from overlapping active regions 308P(1)-308P(3).

In FIG. 3A, M0_PG segment 218(2) substantially overlaps active region 308P(1). In the example of FIG. 3A, M0_PG segment 218(2) substantially asymmetrically overlaps active region 308P(1). Active region 308P(2) of cell region 302(1) is free from being overlapped by an M0_PG segment, e.g., is free from being overlapped by any of M0_PG segments 218(1)-218(5). Bottom boundary 322(1) of cell region 302(1) is overlapped by M0_PG segment 218(3). M0_PG segment 218(3) is (i) adjacent to active region 308P(2) and (ii) is free from overlapping an active region, e.g., is free from overlapping 308P(1)-308P(3).

In FIG. 3A, top boundary 320(2) of cell region 305(1) is adjacent active region 308P(3). Top boundary 320(2) of cell region 305(1) is overlapped by M0_PG segment 218(1). In some embodiments, again, having a top and/or bottom boundary, e.g., 320(2), overlapped by an M0_PG segment, e.g., 218(1) facilitates APR (see FIG. 8). Top boundary 320(2) of cell region 305(1) is free from being overlapped by an active region, e.g., is free from overlapping active regions 308P(1)-308P(3).

In FIG. 3A, bottom boundary 322(2) of cell region 305(1) is between active regions 308P(3) and 308P(1). Bottom boundary 322(2) of cell region 305(1) is free from being overlapped by an M0_PG segment, e.g., is free from being overlapped by any of M0_PG segments 218(1)-218(5). Bottom boundary 322(2) of cell region 305(1) is free from being overlapped by an active region, e.g., is free from overlapping active regions 308P(1)-308P(3). Active region 308P(3) of cell region 305(1) is substantially free from being overlapped by an M0_PG segment, e.g., is substantially free from being overlapped by any of M0_PG segments 218(1)-218(5). M0_PG segment 218(1) is (i) adjacent to active region 308P(3) and (ii) is substantially free from overlapping an active region, e.g., is free from overlapping 308P(1)-308P(3). In some embodiments, active region 308P(3) is a dummy active region. In some embodiments, a dummy active region is filled with a dielectric material. In some embodiments, active region 308P(1) is an N-type active region.

According to a second other approach, two non-CMOS, single height cell regions are stacked on each other relative to the Y-axis (in a non-CMOS two-stack arrangement) which represents a counterpart to cell region 304(1). The counterpart two-stack has: the same width as cell region 304(1); a net height of 2.0*SH; a P-type active region density of 2*d_ARP_SH; and an N-type active region density of 2*d_ARN_SH, where d_ARN_SH≈d_ARP_SH. As compared to the counterpart two-stack, cell region 304(1) has: a density of P-type active region d_ARP_3A≈1.1875*d_AR_SH.

FIG. 3B is a layout diagram of a functional cell region 304(2), in accordance with some embodiments.

Cell region 304(2) includes a cell region 305(2) stacked on a cell region 302(2) relative to the Y-axis. Cell region 302(2) of FIG. 3B is similar to cell region 202(8) of FIG. 2F. Cell region 305(2) is similar to cell region 305(1) of FIG. 3A. For purposes of brevity, the discussion will focus on differences of (i) cell region 302(2) as compared to cell region 202(8) and (ii) cell region 305(2) as compared to cell region 305(1) rather than on similarities.

Cell region 302(2) is a non-CMOS cell region. The active region of cell region 305(2) has the same dopant type as the active regions of cell region 302(2). Hence, cell region 304(2) is a non-CMOS cell region.

Cell region 304(2) is arranged relative to the following: alpha tracks (or alpha lines) α00-α24 that extend parallel to the X-axis, and beta tracks (beta lines) (20-324 that extend parallel to the Y-axis. For simplicity of illustration, not all of the beta tracks are shown in FIG. 3B. In FIG. 3B, each of cell regions 305(2) and 302(2) is aligned to beta tracks β20-β24.

Cell region 304(2) includes: N-type active regions 308N(1)-308N(3); gate segments 310(4)-310(6); dummy gate segments 312(5)-312(8); MD structures (not shown in FIG. 3B but see FIG. 2A); CG shapes 216; CMD shapes (not shown in FIG. 3B but see FIG. 2A); M0_PG segments 218(2)-218(4) amongst M0_PG segments 218(1)-218(5); and instances of M0_RTE segments 219. Gate segments 310(4)-310(5) of cell region 302(2) and gate segment 310(6) of cell region 305(2) are co-track aligned to beta track β22. Dummy gate segments 312(5) and 312(6) of cell region 302(2) are correspondingly aligned to beta tracks β20 and β24 as are dummy gate segments 312(7) and 312(8) of cell region 305(2). M0_PG segments 218(2)-218(4) have a pitch p_218.

In cell region 302(2), each of gate segments 310(4)-310(5), dummy gate segments 312(5)-312(6) and corresponding ones of the MD structures correspondingly overlap active regions 308N(1) and 308N(2). In cell region 305(2), gate segment 310(6), dummy gate segments 312(7)-312(8) and corresponding ones of the MD structures correspondingly overlap active region 308N(3). Cell region 302(2) has left and right boundaries that are correspondingly aligned to beta tracks β20 and β24 as are left and right boundaries of cell region 305(2). Dummy gate segments 312(5) and 312(6) of cell region 302(2) are correspondingly aligned to beta tracks β20 and β24 as are dummy gate segments 312(7) and 312(8) of cell region 305(2).

For cell region 302(2), top 320(3) and bottom 322(3) boundaries correspondingly align to alpha tracks α09 and α18. For cell region 305(2), top 320(4) and bottom 322(4) boundaries correspondingly align to alpha tracks α06 and α09. As cell region 302(2) is stacked under cell region 305(2): top boundary 320(3) of cell region 302(2) is the same as bottom boundary 322(4) of cell region 305(2); and cell region 304(2) has top boundary 320(4) and bottom boundary 322(3).

In some embodiments, top and bottom boundaries of a fabricated cell region (e.g., corresponding to cell region 304(2)) are recognizable as intersecting corresponding instances of dielectric structure 316. In some embodiments, top and bottom boundaries of a fabricated cell region (e.g., corresponding to cell region 304(2)) are recognizable as intersecting corresponding instances of a dielectric structure (see 217), the latter resulting from having trimmed a corresponding MD structure (see 214).

In some embodiments, top and bottom boundaries of a fabricated cell region (e.g., corresponding to cell region 304(2)) are recognizable as follows: an NMOS-triplet of three N-type active region (e.g., 308N(1)-308N(3)) which are adjacent in the second direction (e.g., parallel to the Y-axis) are identified in the fabricated cell region;

a first reference line is identified in the fabricated cell region, where the first reference line extends in the first direction (e.g., parallel to the X-axis) and is adjacent the upper active region (e.g., 308N(3)) of the NMOS-triplet, and where the first reference line intersects a corresponding instance of dielectric structure 316 and instances of counterpart dielectric structures (not shown) that are aligned to alpha track α06 in FIG. 3B;

a second reference line is identified in the fabricated cell region, where the second reference line extends in the first direction and is adjacent the lower active region (e.g., 308N(2)) of the NMOS-triplet, and where the second reference line intersects an instance of dielectric structure 216 and instances of counterpart dielectric structures (not shown) that are aligned to alpha track α18 in FIG. 3B; the top boundary (e.g., 320(4)) of the fabricated cell region is regarded as being the first reference line; and the bottom boundary (e.g., 322(3)) of the fabricated cell region is regarded as being the second reference line.

Relative to the Y-axis, half-height cell region 305(2) has a height of about 0.5*SH, i.e., has a height that is about a 0.5 multiple of the height SH of the single height cell region (see. e.g., instances of cell region 436 of FIG. 4C, instances of cell region 436 of FIG. 4D, or the like). Relative to the Y-axis, active region 208P(3) has width W_AR_min. Like cell region 202(8) of FIG. 2F, cell region 302(2) has a height of about 1.5*SH. Relative to the Y-axis, cell regions 305(2) and 302(2) combined (together) as cell region 304(2) have a height of about 2.0*SH, i.e., have about a 2.0 multiple of the height SH of the single height cell. In some embodiments, cell region 304(2) is used in a footer circuit (see, e.g., FIG. 4B).

In FIG. 3B, top boundary 320(3) of cell region 302(2) is between active regions 308N(1) and 308N(3). Top boundary 320(3) of cell region 302(2) is free from being overlapped by an M0_PG segment, e.g., is free from being overlapped by any of M0_PG segments 218(1)-218(5). Top boundary 320(3) of cell region 302(2) is free from being overlapped by an active region, e.g., is free from overlapping active regions 308N(1)-308N(3). Bottom boundary 322(3) of cell region 302(2) is adjacent active region 308N(2). Bottom boundary 322(3) of cell region 302(2) is overlapped by M0_PG segment 218(4). In some embodiments, having a top and/or bottom boundary, e.g., 322(3), overlapped by an M0_PG segment, e.g., 218(4) facilitates APR (see FIG. 8). Bottom boundary 322(3) of cell region 302(2) is free from being overlapped by an active region, e.g., is free from overlapping active regions 308N(1)-308N(3). M0_PG segment 218(3) substantially overlaps active region 308N(1). In the example of FIG. 3B, M0_PG segment 218(3) substantially asymmetrically overlaps active region 308N(1). Active region 308N(2) of cell region 302(2) is free from being overlapped by an M0_PG segment, e.g., is free from being overlapped by any of M0_PG segments 218(1)-218(5). Bottom boundary 322(3) of cell region 302(2) is overlapped by M0_PG segment 218(4). M0_PG segment 218(4) is (i) adjacent to active region 308N(2) and (ii) is free from overlapping an active region, e.g., is free from overlapping 308N(1)-308N(3). In some embodiments, active region 308N(2) is a P-type active region.

In FIG. 3B, top boundary 320(4) of cell region 305(2) is adjacent active region 308N(3). Top boundary 320(4) of cell region 305(2) is overlapped by M0_PG segment 218(2). In some embodiments, having a top and/or bottom boundary, e.g., 320(4), overlapped by an M0_PG segment, e.g., 218(2) facilitates APR (see FIG. 8). Top boundary 320(4) of cell region 305(2) is free from being overlapped by an active region, e.g., is free from overlapping active regions 308N(1)-308N(3). Bottom boundary 322(4) of cell region 305(2) is between active regions 308N(3) and 308N(1). Bottom boundary 322(4) of cell region 305(2) is free from being overlapped by an M0_PG segment, e.g., is free from being overlapped by any of M0_PG segments 218(1)-218(5). Bottom boundary 322(4) of cell region 305(2) is free from being overlapped by an active region, e.g., is free from overlapping active regions 308N(1)-308N(3). Active region 308N(3) of cell region 305(2) is substantially free from being overlapped by an M0_PG segment, e.g., is substantially free from being overlapped by any of M0_PG segments 218(1)-218(5). M0_PG segment 218(2) is (i) adjacent to active region 308N(3) and (ii) is substantially free from overlapping an active region, e.g., is free from overlapping 308N(1)-308N(3).

FIG. 4A is a macro region 401A that (among other things) includes a header circuit 426A, in accordance with some embodiments.

Macro region 401A is an example of a circuit usable in devices 100A, 100B or 100C. In some embodiments, macro region 401A is an example of macro region 101A. In some embodiments, macro region 401A is an example of macro region 101B. In some embodiments, macro region 401A is an example of macro region 101C.

Macro region 401A includes: header circuit 426A; a gated power circuit 428A; a gated power circuit 428B; and a control circuit 430. In general, power consumption by macro region 401A increases due to leakage currents. Nearly all of the leakage currents are exhibited by gated power circuits 428A & 428B, with only a small fraction of the total leakage being exhibited by header circuit 426A and control circuit 430. In general, power gating is a technique to reduce power consumption in circuits by turning off power supplied to ones of the circuits which are not being used, i.e., to inactive ones of the circuits. The power provided to each of gated power circuits 428A & 428B is gated by corresponding portions of header circuit 426A, hence each of circuits 428A & 428B is referred to herein as a gated power circuit.

In some embodiments, header circuit 426A is comprised of non-CMOS cell regions, e.g., one or more instances of cell region 202(5) and/or one or more instances of cell region 202(6). In some embodiments, header circuit 426A is comprised of one or more instances of two-stack 203(1).

Each of gated power circuits 428A & 428B is a type of circuit which is configured to operate (1) in a normal mode and (2) in a sleep mode. In some embodiments, the sleep mode is referred to as a standby mode, or the like. In the normal mode, an active-high control signal NSLEEPin_bar has a logical high value such that power is provided to each of gated power circuits 428A & 428B. In the normal mode, each of gated power circuits 428A & 428B is being used by macro region 401A and is either active or inactive, with more power being consumed when active than when inactive. Though less power is consumed when each of gated power circuits 428A & 428B is in use albeit inactive, nevertheless significant power is consumed due to leakage currents. In the sleep mode, standby more, or the like, active-high control signal NSLEEPin_bar has a logical low value such that each of gated power circuits 428A & 428B is not being used and so power is temporarily cut off from each of gated power circuits 428A & 428B. Accordingly, in the sleep mode, standby mode, or the like, each of gated power circuits 428A & 428B not only is inactive, but each of circuits 428A & 428B also does not suffer leakage currents.

Header circuit 426A includes field effect transistors (FETs). More particularly, header circuit 426A includes a positive-channel metal-oxide semiconductor (PMOS) FET (PFET) P1 and a PFET P2. A source of PFET P1 and a source of PFET P2 are both configured to receive an ungated version of a reference voltage, e.g., VDD. In FIG. 4A, the ungated version of VDD is referred to as true VDD (TVDD). Furthermore, a body contact of PFET P1 and a body contact of PFET P2 are configured to receive ungated reference voltage TVDD. When transistors P1 and P2 correspondingly are turned on, a drain of PFET P1 and a drain of PFET P2 provide a gated version of TVDD correspondingly to gated power circuits 428A & 428B. In FIG. 4A, the gated version of TVDD is referred to as virtual VDD (VVDD). Assuming that a source-drain voltage drop (Vsd) for each of transistors P1 and P2 is sufficiently small as to be regarded as negligible, VVDD=TVDD−Vsd≈TVDD, and thus VVDD is substantially similar to TVDD. When transistors P1 and P2 correspondingly are turned OFF, power is cut off correspondingly to gated power circuits 428A and 428B.

A gate of PFET P1 and a gate of PFET P2 are both coupled to a node nd1 and are configured to receive control signal NSLEEPin_bar. Header circuit 426A is, and more particularly each of transistors P1 and P2 are, configured to be turned on and off based on control signal NSLEEPin_bar. In some embodiments, header circuit 426A has a different configuration than is shown in FIG. 4A. For example, in some embodiments, header circuit 426A has a single PFET, e.g., P1, which provides VVDD to each of gated power circuits 428A & 428B. In such embodiments in which the current-sourcing capacity of the transistor P1 is sufficient to source each of gated power circuits 428A & 428B, the use of single transistor P1 reduces the area consumed by header circuit 426A.

Control circuit 430 includes a first inverter 432 and a second inverter 434. First inverter 432 is configured to receive control signal NSLEEPin and to invert the same so as to generate control signal NSLEEPin_bar. Thus, if control signal NSLEEPin is received in a high voltage state (e.g., at or near TVDD), then first inverter 432 is configured to generate control signal NSLEEPin_bar at a low voltage state (e.g., at or near VSS). If control signal NSLEEPin is received in a low voltage state (e.g., at or near VSS), then first inverter 432 is configured to generate control signal NSLEEPin_bar at a low voltage state (e.g., at or near TVDD).

In FIG. 4A, first inverter 432 includes a PFET P3 and a negative-channel metal-oxide semiconductor (NMOS) FET (NFET) N1. PFET P3 has a source coupled to receive ungated reference voltage TVDD and a drain coupled to node nd2. A body contact of PFET P3 is coupled to receive ungated reference voltage TVDD. Node nd2 is coupled to node nd1 of header circuit 426A. NMOS transistor N1 has a drain coupled to node nd2 and a source coupled to receive a reference voltage VSS (e.g., a ground voltage). A body contact of NMOS transistor N1 is coupled to receive reference voltage VBB, e.g., VSS. A gate contact of PFET P3 and a gate contact of NMOS transistor N1 are both coupled to node nd3. Control signal NSLEEPin is received at node nd3.

Accordingly, if control signal NSLEEPin is received in a low voltage state (e.g., at or near VSS), PFET P3 turns on and NMOS transistor N1 shuts off. PFET P3 thus pulls the voltage at node nd2 up at or near TVDD so that control signal NSLEEPin_bar is provided at or near TVDD. As such, the voltage at node nd1 is in the high voltage state at or near TVDD. Accordingly, PFET P1 and PFET P2 are shut off and thus power is cut off correspondingly to gated power circuits 428A and 428B.

On the other hand, if control signal NSLEEPin is in a high voltage state (at or near TVDD), PFET P3 shuts off and NMOS transistor N1 turns on. NMOS transistor N1 thus pulls the voltage at node nd2 down at or near VSS so that control signal NSLEEPin_bar is at or near VSS. As such, node nd1 is in the low voltage state at or near VSS. Accordingly, PFET P1 and PFET P2 are turned on to provide gated reference voltage VVDD to gated power circuits 428A & 428B.

Second inverter 434 is configured to generate control signal NSLEEPout from control signal NSLEEPin_bar. More specifically, second inverter 434 is configured to invert control signal NSLEEPin_bar and generate control signal NSLEEPout. Thus, if control signal NSLEEPin_bar is received in a high voltage state (e.g., at or near TVDD), second inverter 434 is configured to generate control signal NSLEEPout at a low voltage state (e.g., at or near VSS). If control signal NSLEEPin_bar is received in a low voltage state (e.g., at or near VSS), second inverter 434 is configured to generate control signal NSLEEPout at a high voltage state (e.g., at or near TVDD).

In FIG. 4A, second inverter 434 includes a PFET P4 and an NFET N2. PFET P4 has a source coupled to receive ungated reference voltage TVDD and a drain coupled to node nd4. A body contact of PFET P4 is coupled to receive ungated reference voltage TVDD. NFET N2 has a drain coupled to node nd4 and a source coupled to receive a reference voltage VSS (e.g., a ground voltage). A body contact of NFET N2 is coupled to receive reference voltage VBB, e.g., VSS. A gate contact of PFET P4 and a gate contact of NFET N2 are both coupled to node nd1. Control signal NSLEEPin_bar is provided at node nd1.

Accordingly, if control signal NSLEEPin_bar is in a low voltage state (e.g., at or near VSS), then PFET P4 turns on and NFET N2 shuts off. PFET P4 thus pulls the voltage at node nd4 up at or near TVDD so that control signal NSLEEPout is at or near TVDD. As such, the voltage at node nd4 is in the high voltage state at or near TVDD. In this manner, control signal NSLEEPout indicates that header circuit 426A is turned on and is providing gated control voltage VVDD to gated power circuits 428A & 428B.

On the other hand, if control signal NSLEEPin′ is in a high voltage state (at or near TVDD), then PFET P4 shuts off and NFET N2 turns on. NFET N2 thus pulls the voltage at node nd4 down at or near VSS so that control signal NSLEEPout is in the low voltage state at or near VSS. In this manner, control signal NSLEEPout indicates that header circuit 426A is turned off so that power is cut off to each of gated power circuits 428A and 428B.

FIG. 4B is a macro region 401B that (among other things) includes a footer circuit 426B, in accordance with some embodiments.

Macro region 401B is an example of a circuit usable in devices 100A, 100B or 100C. In some embodiments, macro region 401B is an example of macro region 101A. In some embodiments, macro region 401B is an example of macro region 101B. In some embodiments, macro region 401B is an example of macro region 101C.

Macro region 401B of FIG. 4B is similar to macro region 401A of FIG. 4A. For purposes of brevity, the discussion will focus on differences of macro region 401B as compared to macro region 401A rather than on similarities. In general, footer circuit 426B of macro region 401B replaces header circuit 426A of macro region 401A. Footer circuit 426B of FIG. 4B is similar to header circuit 426A of FIG. 4A. For purposes of brevity, the discussion will focus on differences of footer circuit 426B as compared to header circuit 426A rather than on similarities. In footer circuit 426B, NFETS N3 and N4 correspondingly replace PFETs P1 and P2 of header circuit 426A. In FIG. 4B, control signal NSLEEPin_bar is active-low whereas control signal NSLEEPin_bar is active-low. As such, in FIG. 4B: in the normal mode, active-low control signal NSLEEPin_bar has a logical low value; and, in the sleep mode, standby more, or the like, active-low control signal NSLEEPin_bar has a logical high value.

In some embodiments, footer circuit 426B is comprised of non-CMOS cell regions, e.g., one or more instances of cell region 202(7) and/or one or more instances of cell region 202(8). In some embodiments, footer circuit 426B is comprised of one or more instances of two-stack 203(2).

FIG. 4C is a floorplan diagram 435C, in accordance with some embodiments.

Floorplan diagram (hereinafter, floorplan) 435C is used, e.g., for header circuit 426A of FIG. 4A, for footer circuit 426B of FIG. 4B, or the like. Floorplan 435C includes cell regions 402(1) and 402(2). Relative to the Y-axis, cell region 402(1) is stacked on cell region 402(2) and together represent a two-stack 403. Cell region 402(1) is an example of cell region 202(5) of FIG. 2E, cell region 202(7) of FIG. 2F, or the like. Cell region 402(2) is an example of cell region 202(6) of FIG. 2E, cell region 202(8) of FIG. 2F, or the like.

Floorplan 435C further includes: to the left of two-stack 403 in correspondingly adjacent or abutting arrangements, three instances of single height cell region 436 stacked on each relative to the Y-axis; and, to the right of two-stack 403 in correspondingly adjacent or abutting arrangements, three instances of single height cell region 436 stacked on each relative to the Y-axis.

FIG. 4D is a floorplan 435D, in accordance with some embodiments.

Floorplan 435D is used, e.g., for header circuit 426A of FIG. 4A, for footer circuit 426B of FIG. 4B, or the like. Floorplan 435D includes a cell region 404(1). Cell region 404(1) is an example of cell region 304(1) of FIG. 3A, cell region 304(2) of FIG. 3B, or the like.

Floorplan 435D further includes: to the left of cell region 404(1) in correspondingly adjacent or abutting arrangements, a first instance of a half-height cell region 438 stacked on a first instance of a single height cell region 436 and a second instance of half-height cell region 438 stacked under the first instance of cell region 436, relative to the Y-axis; and, to the right of two-stack 403 in correspondingly adjacent or abutting arrangements, a third instance of a half-height cell region 438 stacked on a second instance of a single height cell region 436 and a fourth instance of half-height cell region 438 stacked under the second instance of cell region 436, on each relative to the Y-axis.

FIG. 4E is a layout diagram of a macro region 401E, in accordance with some embodiments.

Macro region 401E is an example of header circuit 426A of FIG. 4A, footer circuit 426B of FIG. 4B, or the like. The floorplan used in macro region 401E is an example of floorplan 435C of FIG. 4C.

Macro region 401E includes: single height cell regions 436(1)-436(6); three-halves height cell regions 402(3) and 402(4); and various instances of a dummy active region 440. Cell regions 436(1)-436(3) of FIG. 4E correspond to the three stacked instances of single height cell region 436 shown to the left of two-stack 403 of FIG. 4C. Cell regions 436(4)-436(6) of FIG. 4E correspond to the three stacked instances of single height cell region 436 shown to the right of two-stack 403 of FIG. 4C. Cell region 402(3) of FIG. 4E corresponds to cell region 402(1) of FIG. 4C. Cell region 402(4) of FIG. 4E corresponds to cell region 402(2) of FIG. 4C. Relative to the X-axis, instances of dummy active region 440 correspondingly are: between (i) cell regions 436(1)-436(3) and (ii) cell regions 402(3)-402(4); and between (iii) cell regions 402(2)-402(3) and (iv) cell regions 436(4)-436(6). In some embodiments, dummy active region 440 is referred to as padding 440.

FIG. 4F is a layout diagram of a macro region 401F, in accordance with some embodiments.

Macro region 401F is an example of header circuit 426A of FIG. 4A, footer circuit 426B of FIG. 4B, or the like. The floorplan used in macro region 401F is an example of floorplan 435D of FIG. 4D. Macro region 401F includes: half-height cell regions 438(1)-438(4); single height cell regions 436(7)-436(8); a double height cell region 404(2); and various instances of dummy active region 440. Cell region 438(1) of FIG. 4F corresponds to the first instance of half-height cell region 438 of FIG. 4D. Cell region 438(2) of FIG. 4F corresponds to the second instance of half-height cell region 438 of FIG. 4D. Cell region 438(3) of FIG. 4F corresponds to the third instance of half-height cell region 438 of FIG. 4D. Cell region 438(4) of FIG. 4F corresponds to the fourth of half-height cell region 438 of FIG. 4D. Cell region 404(2) of FIG. 4F corresponds to cell region 404(1) of FIG. 4D. Relative to the X-axis, instances of dummy active region 440 correspondingly are: between (i) cell regions 438(1), 436(7) and 438(2) and (ii) cell region 404(2); and between (iii) cell region 404(2) and (iv) cell regions 438(3), 436(8) and 438(4).

According to a third other approach, a macro region which includes only instances of a single height cell region represents a counterpart to the first cell. Due at least in part, e.g., to the greater active region density of double height cell region 404(2) and thereby of macro region 401F as compared to the counterpart macro region, macro region 401F exhibits a better R_on than the counterpart macro region. In some embodiments, R_on represents resistance of the macro as a whole during startup (or turn-on), i.e., turn-on resistance of the macro as a whole. In some embodiments, R_on of macro region 401F is lower than R_on of the counterpart macro region.

FIG. 5A and 5B are cross-sectional views 502A and 502B of corresponding functional cell regions, in accordance with some embodiments.

In particular, FIG. 5A is cross sectional view of a cell region based on cell region 202(1) of FIG. 2A. FIG. 5A corresponds to section line 5A-5A′ of FIG. 2A. FIG. 5B is cross sectional view of a cell region based on cell region 304(1) of FIG. 3A. FIG. 5B corresponds to section line 5B-5B′ of FIG. 3A.

Each of FIGS. 5A-5B includes: an active region layer 554; a transistor-components layer 556; and MET0 layer 558. Each of FIGS. 5A-5B further includes: a P-type substrate 542; an N-well 544 formed in substrate 542; P-type fins 548 formed partially in N-well 544 relative to the Z-axis; fin-insulator 546 formed against fins 548; and a gate insulating layer 552 formed on fins 548, the upper surface of N-well 544, the upper surface of fin-insulator 546 and substrate 524. FIG. 5A additionally includes N-type fins 550 formed partially in substrate 534 relative to the Z-axis. In FIG. 5A, gate insulating layer 552 is also formed on fins 550.

FIG. 5A further includes gate segments 510(2) and 510(3). In FIG. 5A: fins 548 under gate segment 510(2) represent an active region 508P(1) corresponding to active region 208P(1) of FIG. 2A; and fins 550 under gate segment 510(1) represent an active region 508N(1) corresponding to active region 20NP(1) of FIG. 2A.

FIG. 5B further includes gate segments 510(3), 510(4) and 510(5). In FIG. 5B: fins 548 under gate segment 510(3) represent an active region 508P(2) corresponding to active region 308P(2) of FIG. 3A; fins 548 under gate segment 510(4) represent an active region 508P(3) corresponding to active region 308P(1) of FIG. 3A; and fins 548 under gate segment 510(5) represent an active region 508P(4) corresponding to active region 308P(3) of FIG. 3A.

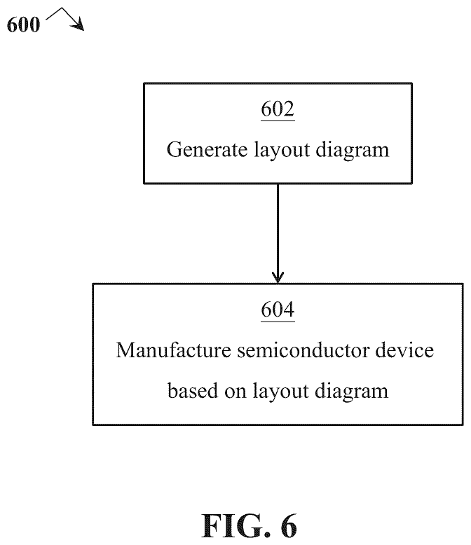

FIG. 6 is a flowchart (flow diagram) of a method 600 of manufacturing device, in accordance with some embodiments.

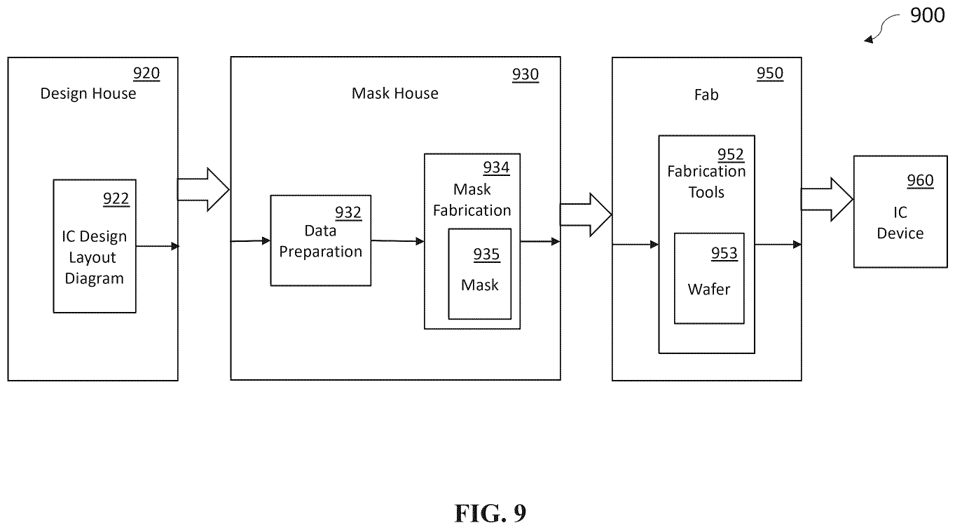

Method 600 is implementable, for example, using EDA system 800 (FIG. 8, discussed below) and an IC manufacturing system 900 (FIG. 9, discussed below), in accordance with some embodiments. Examples of cell regions and/or macro regions which can be manufactured according to method 600 include the cell regions and/or macro regions disclosed herein, or the like.

In FIG. 6, method 600 includes blocks 602-604. At block 602, a layout diagram is generated which, among other things, includes one or more layout diagrams corresponding to one or more of the cell regions herein, one or more of the macro regions disclosed herein, or the like. Block 602 is implementable, for example, using EDA system 800 (FIG. 8, discussed below), in accordance with some embodiments. From block 602, flow proceeds to block 604.

At block 604, based on the layout diagram, at least one of (A) one or more photolithographic exposures are made or (b) one or more photolithography masks are fabricated or (C) one or more components in a layer of a device, e.g., a device is fabricated. See discussion below of IC manufacturing system 900 in FIG. 9 below.

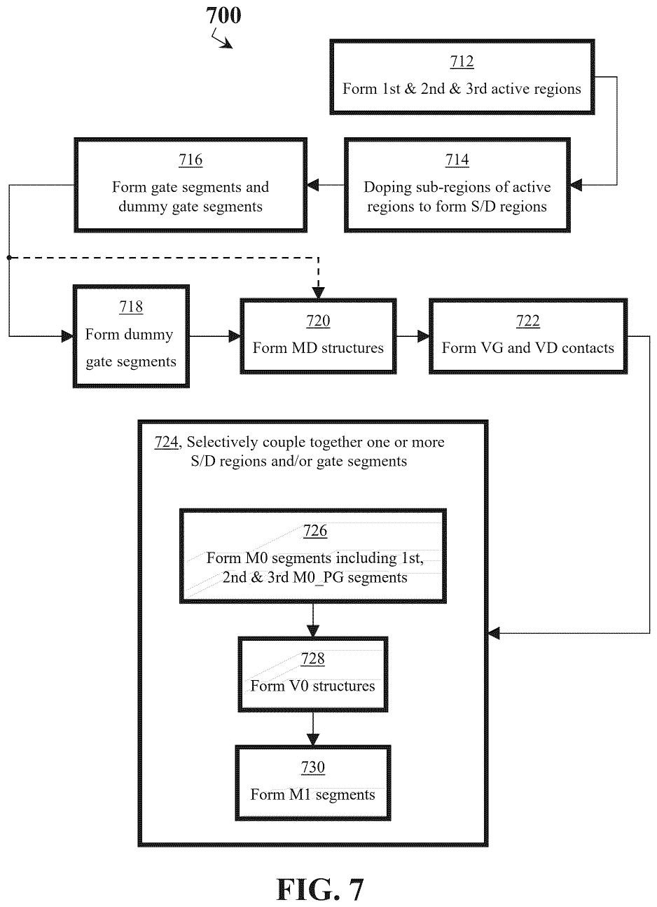

FIG. 7 is a flowchart of a method 700 of manufacturing a device, in accordance with some embodiments.

Method 700 is an example of block 604 (see FIG. 6, discussed above). Method 700 is implementable, for example, using IC manufacturing system 900 (see FIG. 9, discussed below), in accordance with some embodiments. Examples of a devices which can be manufactured according to method 700 include devices that include one or more of the devices disclosed herein, devices including one or more of the macro regions disclosed herein, devices including one or more of the cell regions disclosed herein, or the like. Method 700 includes blocks 712-730.

At block 712, first, second and third active regions that extend in a first direction (e.g., parallel to the X-axis), are formed. Examples of the first active region include active regions 208N(1) in FIGS. 2A and 2C, 208P(2) in FIGS. 2B and 2D, 208P(5) in FIGS. 2E, 208N(5) in FIGS. 2F, 308P(1) in FIGS. 3A, 308N(1) in FIGS. 3B, 508N(1) in FIGS. 5A, 508P(2) in FIG. 5B, or the like. Examples of the second active region include 208P(1) in FIGS. 2A and 2C, 208N(2) in FIGS. 2B and 2D, 208P(6) in FIGS. 2E, 208N(6) in FIGS. 2F, 308P(2) in FIGS. 3A, 308N(2) in FIGS. 3B, 508P(1) in FIGS. 5A, 508P(3) in FIG. 5B, or the like. Examples of the third active region include 208N(3) in FIGS. 2C, 208P(4) in FIGS. 2D, 208P(7) in FIGS. 2E, 208N(7) in FIGS. 2F, 308P(3) in FIGS. 3A, 308N(3) in FIGS. 3B, 508P(4) in FIG. 5B, or the like. From block 712, flow proceeds to block 714.

In some embodiments, at block 712, a fourth active region that extends in the first direction (e.g., parallel to the X-axis), is formed. Examples of the fourth active region include 208P(3) in FIGS. 2C, 208N(4) in FIGS. 2D, 208P(8) in FIGS. 2E and 208N(8) in FIG. 2F, or the like. Again, from block 712, flow proceeds to block 714.

At block 714, sub-regions of the ARs are doped to form S/D regions. Example locations of the S/D regions include intersections where an MD structures overly corresponding active regions, e.g., as in FIGS. 2A-2B, or the like. From block 714, flow proceeds to block 716.

At block 716, gate segments and dummy gate segments that extend in a second direction (e.g., parallel to the Y-axis) and are over one or more of the first, second and third active regions are formed, the gate segments including first, second and third gate segments, the second direction being perpendicular to the first direction. Examples of the first gate segment include gate segments 210(1) in FIGS. 2A, 2C and 2E, 210(3) in FIGS. 2B, 2D and 2F, 310(1) in FIGS. 3A and 310(4) in FIG. 3B, or the like. Examples of the second gate segment include gate segments 210(2) in FIGS. 2A, 2C and 2E, 210(4) in FIGS. 2B, 2D and 2F, 310(2) in FIGS. 3A and 310(5) in FIG. 3B, or the like. Examples of the third gate segment include gate segments 210(5) in FIGS. 2C and 2E, 210(7) in FIGS. 2D and 2F, 310(3) in FIGS. 3A and 310(6) in FIG. 3B, or the like. From block 716, flow proceeds to block 718.

In some embodiments, at block 716, a fourth gate segment that extends in the second direction (e.g., parallel to the Y-axis) and is over one or more of the first, second and third active regions is formed. Examples of the fourth gate segment include gate segments 210(6) in FIGS. 2C and 2E, and 210(8) in FIGS. 2D and 2F, or the like. Again, from block 716, flow proceeds to block 718.

At block 718, dummy gate segments are formed converted into IDG structures are formed. Discussion of dummy gate segments is included in the discussion of FIG. 2A. Examples of the dummy gate segments include dummy gate segments 212(1)-212(2) in FIGS. 2A, 2C and 2E, 212(3)-212(4) in FIGS. 2B, 2D and 2F, 212(5)-212(6) in FIGS. 2E, 212(7)-212(8) in FIGS. 2F, 312(1)-312(4) in FIGS. 3A and 312(5)-312(8) in FIG. 3B, or the like. From block 718, flow proceeds to block 720.

At block 720, MD structures (e.g., 216 in FIGS. 2A-2B, or the like) are formed. From block 720, flow proceeds to block 722.

At block 722, VG contacts (not shown) and VD contacts (not shown) are formed over corresponding (A) ones of the gate segments and (B) ones of the MD structures. From block 722, flow proceeds to block 724.

At block 724, one or more of the S/D regions and/or one or more of the gate segments are coupled together to form corresponding transistors. Within block 724, flow proceeds to block 726.

At block 726, in a first metallization layer (M_1st layer), M0 segments that extend in the second direction (e.g., parallel to the Y-axis) and are over (A) corresponding ones of the VG contacts and/or (B) corresponding ones of the VD contacts are formed, the M0 segments including adjacent first, second and third M_1st power grid (PG) segment. An example of the M_1st layer is layer MET0 shown as 558 in FIGS. 5A-5B, or the like. Examples of the M0 segments include M0_PG segments 218(1)-218(5) in FIGS. 2A-2B and 3A-3B, 218(6) in FIGS. 2C-2E, 518(2)-518(3) and 519 in FIGS. 5A-5B, or the like. More particularly, examples of the first M_1st PG segment include M0_PG segments 218(2) in FIGS. 2A, 2C, 2E and 3A, 218(3) in FIGS. 2B, 2D, 2F and 3B, or the like. More particularly, examples of the second M_1st PG segment include M0_PG segments 218(3) in FIGS. 2A, 2C, 2E and 3A, 218(4) in FIGS. 2B, 2D, 2F and 3B, or the like. More particularly, examples of the third M_1st PG segment include M0_PG segments 218(1) in FIGS. 2A, 2C, 2E and 3A, 218(2) in FIGS. 2B, 2D, 2F and 3B, or the like. From block 726, flow proceeds to block 728.

In some embodiments, at block 726, in the M_1st layer, fourth and fifth M_1st PG segments that extend in the second direction (e.g., parallel to the Y-axis) and are over (A) corresponding ones of the VG contacts and/or (B) corresponding ones of the VD contacts are formed. Examples of the fourth M_1st PG segment include M0_PG segments 218(4) in FIGS. 2A, 2C, 2E and 3A, 218(5) in FIGS. 2B, 2D, 2F and 3B, or the like. Examples of the fifth M_1st PG segment include M0_PG segments 218(5) in FIGS. 2C and 2E, 218(6) in FIG. 2F, or the like. Again, from block 726, flow proceeds to block 728.

At block 728, VO structures (not shown) are formed over corresponding ones of the M0 segments. From block 728, flow proceeds to block 730.

At block 730, M1 segments (not shown) are formed over corresponding ones of the VO structures.

In some embodiments, blocks 712 and 716 result in the following including: top (e.g., 220(1/2)) and bottom (e.g., 222(1/2)) boundaries of the first cell region (e.g., 202(1)) aligning to corresponding ones of alpha tracks (e.g., α(x)_X-axis); the first M_1st PG segment (e.g., 218(2)/218(3)) substantially asymmetrically overlapping the first active region (e.g., 208N(1)/208P(2)); the second M_1st PG segment (e.g., 218(3)/218(4)) overlapping the bottom boundary (e.g., 222(1/2)), being adjacent to the second active region (e.g., 208P(1)/208N(2)) and substantially free from overlapping the first (e.g., 208N(1)/208P(2)) and second (e.g., 208P(1)/208N(2)) active regions; and the top boundary (e.g., 220(1/2)) being between, and substantially free from overlapping each of the first active region (e.g., 208N(1)/208P(2)) and the third M_1st PG segment (e.g., 218(1)/218(2)).

In some embodiments, blocks 712 and 716 result in the following including: top (e.g., 320(1/2)) and bottom (e.g., 322(1/2)) boundaries of the first cell region (e.g., 304(1)) aligning to corresponding ones of alpha tracks (e.g., α(x)_X-axis); the first M_1st PG segment (e.g., 218(2)/218(3)) substantially asymmetrically overlapping the first active region (e.g., 308P(1)/308N(1)); each of the second (e.g., 218(3)/218(4)) and third (e.g., 218(1)/218(2)) M_1st PG segments being substantially free from overlapping an active region; the second M_1st PG segment (e.g., 218(3)/218(4)) overlapping the bottom boundary (e.g., 322(1/2)) and being adjacent to the second active region (e.g., 308P(2)/308N(2)); and the third M_1st PG segment (e.g., 218(1)/218(2)) overlapping the top boundary (e.g., 320(1/2)) and being adjacent to the third active region (e.g., 308P(3)/308N(3)).

In some embodiments, block 716 results in the following including: each of the gate segments aligning to corresponding ones of beta tracks (e.g., β(y)_Y-axis); and (A) the first (e.g., 210(1/3)) and second (e.g., 210(2/4)) gate segments being aligned to a same one of the beta tracks (e.g., β(y)_Y-axis) or (B) the first (e.g., 310(1/4x)), second (e.g., 310(2/5)) and third (e.g., 310(3/6)) gate segments being aligned to a same one of the beta tracks (e.g., β(y)_Y-axis).

In some embodiments, block 716 further results in the following including: the first (e.g., 210(1/3)) and second (e.g., 210(2/4)) gate segments correspondingly representing first and second portions of a same one of the gate segments; or the first (e.g., 310(1/4x)), second (e.g., 310(2/5)) and third (e.g., 310(3/6)) gate segments correspondingly representing first and second portions of a same one of the gate segments

In some embodiments, the M_1st PG segments have a first pitch (e.g., p_218) and block 726 further results in the following including M_1st routing segments (e.g., 219) aligning to corresponding ones of the alpha tracks (e.g., α(x)_X-axis) and having a second pitch (e.g., p_219) such that the second pitch (e.g., p_219) is smaller than the first pitch (e.g., p_218).

In some embodiments, the M_1st PG segments have a first pitch (e.g., p_218); and, regarding a height (e.g., 1.5*SH} of the first cell region (e.g., 202(1)} that is defined as a distance between the top (e.g., 220(1/2)} and bottom (e.g., 222(1/2)} boundaries of the first cell region (e.g., 202(1)}, blocks 712 and 716 further result in the following including the height (e.g., 1.5*SH} of the first cell region (e.g., 202(1)} being about 1.5 times the first pitch (e.g., p_218}.

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a processor 802 (e.g., a hardware processor) and a non-transitory, computer-readable storage medium 804. Storage medium 804, amongst other things, is encoded with, i.e., stores, computer program code 806, i.e., a set of executable instructions. Execution of instructions 806 by processor 802 represents (at least in part) an EDA tool which implements a portion of or all, e.g., one or more methods of generating layout diagrams corresponding to the layout diagrams disclosed herein, or the like, in accordance with one or more embodiments (hereinafter, the noted processes and/or methods).

Storage medium 804, amongst other things, stores layout diagrams 811 such as the layout diagrams disclosed herein, other the like.

Processor 802 is electrically coupled to storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and storage medium 804 are capable of connecting to external elements via network 814. Processor 802 is configured to execute computer program code 806 encoded in storage medium 804 in order to cause EDA system 800 to be usable for performing a portion of or all the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, storage medium 804 is an electronic, magnetic, optical, electromagnetic, infrared, and/or a semiconductor system (or apparatus or device). For example, storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, storage medium 804 includes a compact disk-read only memory (CD-ROM), a compact disk-read/write (CD-R/W), and/or a digital video disc (DVD).

In one or more embodiments, storage medium 804 stores instructions, i.e., computer program code 806 configured to cause EDA system 800 (where such execution represents (at least in part) the EDA tool) to be usable for performing a portion of or all the noted processes and/or methods. In one or more embodiments, storage medium 804 further stores information which facilitates performing a portion of or all the noted processes and/or methods. In one or more embodiments, storage medium 804 stores library 807 of standard cells including standard cells that correspond to components of the layout diagrams disclosed herein. Storage medium 804 stores one or more layout diagrams 816 such as one or more layout diagrams corresponding to the layout diagrams disclosed herein, one or more compiled macros 817 based on layout diagrams including one or more of the layout diagrams disclosed herein, or the like.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows EDA system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion of or all noted processes and/or methods, is implemented in two or more EDA systems 800.

EDA system 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion of or all the noted processes and/or methods is implemented as a standalone software application for execution by a processor. In some embodiments, a portion of or all the noted processes and/or methods is implemented as a software application that is a part of an additional software application. In some embodiments, a portion of or all the noted processes and/or methods is implemented as a plug-in to a software application. In some embodiments, at least one of the noted processes and/or methods is implemented as a software application that is a portion of an EDA tool. In some embodiments, a portion of or all the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

In some embodiments, based on the layout diagram generated by block 602 of FIG. 6, the IC manufacturing system 900 implements block 604 of FIG. 6 wherein at least one of (A) one or more semiconductor masks or (B) at least one component in a layer of an inchoate semiconductor integrated circuit is fabricated using manufacturing system 900. In some embodiments, the IC manufacturing system 900 implements the flowcharts of FIG. 6, or the like.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a semiconductor device includes a first cell region including: first and second active regions extending in a first direction, being adjacent relative to a perpendicular second direction; gate segments including first and second gate segments, each of the gate segments extending in the second direction and being over one or more of the first and second active regions; first and second insulation structures adjacent ends correspondingly of the first and second gate segments; and in a first metallization (M_1st) layer over the gate segments, M_1st power grid (PG) segments including adjacent first, second and third M_1st PG segments correspondingly configured for first, second and the first reference voltages, the first and second reference voltages being different, the M_1st PG segments extending in the first direction, and aligning to corresponding ones of alpha tracks; top and bottom boundaries of the first cell region extending in the first direction, being at least proximal to the first and second insulation structures, and aligning to corresponding ones of alpha tracks; the first M_1st PG segment substantially asymmetrically overlapping the first active region; the second M_1st PG segment overlapping the bottom boundary, being adjacent to the second active region and substantially free from overlapping the first and second active regions; and the top boundary being between, and substantially free from overlapping each of the first active region and the third M_1st PG segment.

In some embodiments, each of the gate segments align to corresponding ones of beta tracks; and the first and second gate segments are aligned to a same one of the beta tracks.

In some embodiments, the first and second gate segments correspondingly represent first and second portions of a same one of the gate segments.

In some embodiments, the M_1st PG segments have a first pitch; and the semiconductor device further includes: in the M_1st layer, M_1st routing segments aligning to corresponding ones of the alpha tracks and having a second pitch; and the second pitch is smaller than the first pitch.

In some embodiments, the M_1st PG segments have a first pitch; and regarding a height of the first cell region that is defined as a distance between the top and bottom boundaries of the first cell region, the height of the first cell region is about 1.5 times the first pitch.

In some embodiments, the first and second active regions are configured correspondingly for different first and second dopant types.

In some embodiments, the first and second active regions are configured for a same first dopant type.

In some embodiments, the semiconductor device further includes a second cell region including: third and fourth active regions extending in the first direction and being adjacent relative to the second direction; and wherein the second cell region is stacked under the first cell region such that the fourth active region is adjacent to the second active region; the gate segments further include third and fourth gate segments over one or more of the third and fourth active regions; the M_1st PG segments further include adjacent fourth and fifth M_1st PG segments correspondingly configured for the first and second reference voltages, the fourth M_1st PG segment being adjacent to the second M_1st PG segment; top and bottom boundaries of the second cell region extending in the first direction {X-axis}, being at least proximal to the third and fourth insulation structures, and aligning to corresponding ones of the alpha tracks; the second cell region is stacked on the first cell region such that the bottom boundary of the first cell region is a same as the top boundary of the second cell region; the fourth M_1st PG segment substantially asymmetrically overlaps the third active region; the second M_1st PG segment overlaps the top boundary of the second cell region is adjacent to the fourth active region and substantially free from overlapping the third and fourth active regions; and the bottom boundary of the second cell region is between, and free from overlapping each of the fourth active region and the fifth M_1st PG segment.

In some embodiments, the first and second active regions are configured correspondingly for different first and second dopant types.

In some embodiments, the first and second active regions are configured correspondingly for a same first dopant type.

In some embodiments, relative to the second direction, each of the first and second active regions has substantially a same width.

In some embodiments, first and second gate segments are adjacent and substantially collinear; proximal ends correspondingly of the first and second gate segments are between the first and second active regions; and the first and second insulation structures are adjacent distal ends correspondingly of the first and second gate segments.

In some embodiments, a semiconductor device includes a first cell region including: first, second and third active regions extending in a first direction, being adjacent relative to a perpendicular second direction; gate segments including first, second and third gate segments, each of the gate segments extending in the second direction and being over one or more of the first, second and second active regions; first and second insulation structures adjacent ends correspondingly of the second and third gate segments; and in a first metallization (M_1st) layer over the gate segments, M_1st power grid (PG) segments including adjacent first, second and third M_1st PG segments correspondingly configured for first, second and the first reference voltages, the first and second reference voltages being different, the M_1st PG segments extending in the first direction, and aligning to corresponding ones of alpha tracks; top and bottom boundaries of the first cell region extending in the first direction, being at least proximal to the first and second insulation structures, and aligning to corresponding ones of alpha tracks; the first M_1st PG segment substantially asymmetrically overlapping the first active region; each of the second and third M_1st PG segments being substantially free from overlapping an active region; the second M_1st PG segment overlapping the bottom boundary and being adjacent to the second active region; and the third M_1st PG segment overlapping the top boundary and being adjacent to the third active region.

In some embodiments, the M_1st PG segments have a first pitch; and regarding a height of the first cell region that is defined as a distance between the top and bottom boundaries of the first cell region, the height of the first cell region is about 2.0 times the first pitch.

In some embodiments, the first, second and second active regions are configured for a same first dopant type.

In some embodiments, relative to the second direction, each of the first and second active regions has substantially a same width W1, and a width W2 of the third active region is about two-thirds W1 such that W2=(0.71)*W1.

In some embodiments, a method (of forming a first cell region of a semiconductor device) includes: forming active regions extending in a first direction and including first and second active regions; forming gate segments extending in a second direction and over one or more of the first and second active regions, the gate segments including first and second gate segments, the second direction being perpendicular to the first direction; trimming the forming gate segments including: forming first and second insulation structures adjacent ends correspondingly of the first and second gate segments; and forming segments (M_1st segments) in a first metallization layer (M_1st layer) that extend in the first direction and align to alpha tracks, the M_1st layer being over the gate segments, the forming M_1st segments resulting in M_1st power grid (PG) segments including adjacent first, second and third M_1st PG segments correspondingly configured for first, second and the first reference voltages, the first and second reference voltages being different; the forming active regions and the forming gate segments resulting in as follows including, top and bottom boundaries of the first cell region extending in the first direction, being at least proximal to the first and second insulation structures, and aligning to corresponding ones of alpha tracks, the first M_1st PG segment substantially asymmetrically overlapping the first active region, the second M_1st PG segment overlapping the bottom boundary, being adjacent to the second active region and substantially free from overlapping the first and second active regions, and the top boundary being between, and substantially free from overlapping each of the first active region and the third M_1st PG segment.

In some embodiments, the forming gate segments further results in as follows including, each of the gate segments aligning to corresponding ones of beta tracks; and the first and second gate segments being aligned to a same one of the beta tracks.

In some embodiments, the forming gate segments further results in as follows including, the first and second gate segments correspondingly representing first and second portions of a same one of the gate segments.

In some embodiments, the M_1st PG segments have a first pitch, the forming M_1st segments further resulting as follows including, M_1st routing segments aligning to corresponding ones of the alpha tracks and having a second pitch; and the second pitch is smaller than the first pitch.

In some embodiments, the M_1st PG segments have a first pitch; and the forming active regions and the forming gate segments resulting in as follows including, regarding a height of the first cell region that is defined as a distance between the top and bottom boundaries of the first cell region, the height of the first cell region being about 1.5 times the first pitch.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A semiconductor device comprising a first cell region including:
first and second active regions extending in a first direction, being adjacent relative to a perpendicular second direction;
gate segments including first and second gate segments, each of the gate segments extending in the second direction and being over one or more of the first and second active regions;
first and second insulation structures adjacent ends correspondingly of the first and second gate segments; and
in a first metallization (M_1st) layer over the gate segments, M_1st power grid (PG) segments including adjacent first, second and third M_1st PG segments correspondingly configured for first, second and the first reference voltages, the first and second reference voltages being different,
the M_1st PG segments extending in the first direction, and aligning to corresponding ones of alpha tracks;
top and bottom boundaries of the first cell region extending in the first direction, being at least proximal to the first and second insulation structures, and aligning to corresponding ones of alpha tracks;
the first M_1st PG segment substantially asymmetrically overlapping the first active region;
the second M_1st PG segment overlapping the bottom boundary, being adjacent to the second active region and substantially free from overlapping the first and second active regions; and
the top boundary being between, and substantially free from overlapping each of the first active region and the third M_1st PG segment.

2. The semiconductor device of claim 1, wherein:
each of the gate segments align to corresponding ones of beta tracks; and
the first and second gate segments are aligned to a same one of the beta tracks.

3. The semiconductor device of claim 2, wherein:
the first and second gate segments correspondingly represent first and second portions of a same one of the gate segments.

4. The semiconductor device of claim 1, wherein:
the M_1st PG segments have a first pitch; and
the semiconductor device further comprises:
in the M_1st layer, M_1st routing segments aligning to corresponding ones of the alpha tracks and having a second pitch; and
the second pitch is smaller than the first pitch.

5. The semiconductor device of claim 1, wherein:
the M_1st PG segments have a first pitch; and
regarding a height of the first cell region that is defined as a distance between the top and bottom boundaries of the first cell region,
the height of the first cell region is about 1.5 times the first pitch.

6. The semiconductor device of claim 1, wherein:
the first and second active regions are configured correspondingly for different first and second dopant types.

7. The semiconductor device of claim 1, wherein:
the first and second active regions are configured for a same first dopant type.

8. The semiconductor device of claim 1, further comprising a second cell region including:
third and fourth active regions extending in the first direction and being adjacent relative to the second direction; and
wherein:
the second cell region is stacked under the first cell region such that the fourth active region is adjacent to the second active region;
the gate segments further include third and fourth gate segments over one or more of the third and fourth active regions;
third and fourth insulation structures adjacent ends correspondingly of the third and fourth gate segments;
the M_1st PG segments further include adjacent fourth and fifth M_1st PG segments correspondingly configured for the first and second reference voltages, the fourth M_1st PG segment being adjacent to the second M_1st PG segment;
top and bottom boundaries of the second cell region extending in the first direction {X-axis}, being at least proximal to the third and fourth insulation structures, and aligning to corresponding ones of the alpha tracks;
the second cell region is stacked on the first cell region such that the bottom boundary of the first cell region is a same as the top boundary of the second cell region;
the fourth M_1st PG segment substantially asymmetrically overlaps the third active region;
the second M_1st PG segment overlaps the top boundary of the second cell region is adjacent to the fourth active region and substantially free from overlapping the third and fourth active regions; and
the bottom boundary of the second cell region is between, and free from overlapping each of the fourth active region and the fifth M_1st PG segment.

9. The semiconductor device of claim 8, wherein:
the first and second active regions are configured correspondingly for different first and second dopant types.

10. The semiconductor device of claim 8, wherein:
the first and second active regions are configured correspondingly for a same first dopant type.

11. The semiconductor device of claim 1, wherein:
relative to the second direction, each of the first and second active regions has substantially a same width.

12. A semiconductor device comprising a first cell region including:
first, second and third active regions extending in a first direction, being adjacent relative to a perpendicular second direction;
gate segments including first, second and third gate segments, each of the gate segments extending in the second direction and being over one or more of the first, second and second active regions;
first and second insulation structures adjacent ends correspondingly of the second and third gate segments; and
in a first metallization (M_1st) layer over the gate segments, M_1st power grid (PG) segments including adjacent first, second and third M_1st PG segments correspondingly configured for first, second and the first reference voltages, the first and second reference voltages being different,
the M_1st PG segments extending in the first direction, and aligning to corresponding ones of alpha tracks;
top and bottom boundaries of the first cell region extending in the first direction, being at least proximal to the first and second insulation structures, and aligning to corresponding ones of alpha tracks;
the first M_1st PG segment substantially asymmetrically overlapping the first active region;
each of the second and third M_1st PG segments being substantially free from overlapping an active region;
the second M_1st PG segment overlapping the bottom boundary and being adjacent to the second active region; and
the third M_1st PG segment overlapping the top boundary and being adjacent to the third active region.

13. The semiconductor device of claim 12, wherein:
the M_1st PG segments have a first pitch; and
regarding a height of the first cell region that is defined as a distance between the top and bottom boundaries of the first cell region,
the height of the first cell region is about 2.0 times the first pitch.

14. The semiconductor device of claim 12, wherein:
the first, second and third active regions are configured for a same first dopant type.

15. The semiconductor device of claim 12, wherein:
relative to the second direction,
each of the first and second active regions has substantially a same width W1, and
a width W2 of the third active region is about two-thirds W1 such that W2≈(0.71)*W1.

16. A method of forming a first cell region of a semiconductor device, the method comprising:
forming active regions extending in a first direction and including first and second active regions;
forming gate segments extending in a second direction and over one or more of the first and second active regions, the gate segments including first and second gate segments, the second direction being perpendicular to the first direction;
trimming the forming gate segments including:
forming first and second insulation structures adjacent ends correspondingly of the first and second gate segments; and
forming segments (M_1st segments) in a first metallization layer (M_1st layer) that extend in the first direction and align to alpha tracks, the M_1st layer being over the gate segments, the forming M_1st segments resulting in M_1st power grid (PG) segments including adjacent first, second and third M_1st PG segments correspondingly configured for first, second and the first reference voltages, the first and second reference voltages being different;
the forming active regions and the forming gate segments resulting in as follows including,
top and bottom boundaries of the first cell region extending in the first direction, being at least proximal to the first and second insulation structures, and aligning to corresponding ones of alpha tracks,
the first M_1st PG segment substantially asymmetrically overlapping the first active region,
the second M_1st PG segment overlapping the bottom boundary, being adjacent to the second active region and substantially free from overlapping the first and second active regions, and
the top boundary being between, and substantially free from overlapping each of the first active region and the third M_1st PG segment.

17. The method of claim 16, wherein:
the forming gate segments further results in as follows including,
each of the gate segments aligning to corresponding ones of beta tracks; and
the first and second gate segments being aligned to a same one of the beta tracks.

18. The method of claim 16, wherein:
the forming gate segments further results in as follows including,
the first and second gate segments correspondingly representing first and second portions of a same one of the gate segments.

19. The method of claim 16, wherein:
the M_1st PG segments have a first pitch,
the forming M_1st segments further resulting as follows including,
M_1st routing segments aligning to corresponding ones of the alpha tracks and having a second pitch; and
the second pitch is smaller than the first pitch.

20. The method of claim 16, wherein:
the M_1st PG segments have a first pitch; and
the forming active regions and the forming gate segments resulting in as follows including,
regarding a height of the first cell region that is defined as a distance between the top and bottom boundaries of the first cell region,
the height of the first cell region being about 1.5 times the first pitch.
